(19) United States
(12) Patent Application Publication
(10) Pub. No.: US 2025/0311409 A1
(43) Pub. Date: Oct. 2, 2025

(54) ETCH STOP ARCHITECTURES FOR POWER DEVICE AND PASSIVE COMPONENTS

(71) Applicant: TEXAS INSTRUMENTS INCORPORATED, Dallas, TX (US)

(72) Inventors: Zhikai Tang, Sunnyvale, CA (US); Ujwal Radhakrishna, San Jose, CA (US); Jungwoo Joh, Allen, TX (US); Timothy Merkin, Princeton, TX (US)

(21) Appl. No.: 18/619,011

(22) Filed: Mar. 27, 2024

(51) Int. Cl. H01L 27/088; H01L 21/311; H01L 21/768; H01L 23/532; H01L 27/06; H01L 29/20; H01L 29/40; H01L 29/66; H01L 29/778

(52) U.S. Cl. CPC H10D 84/84; H01L 21/31144; H01L 21/76832; H01L 23/53295; H10D 30/015; H10D 30/475; H10D 62/8503; H10D 64/112; H10D 84/811

(57) ABSTRACT

A semiconductor device includes a semiconductor substrate; a source electrode, a gate electrode, and a drain electrode on the semiconductor substrate; a staircase dielectric structure on the semiconductor substrate and laterally between the gate electrode and the drain electrode; and a metal layer on the staircase dielectric structure. The staircase dielectric structure includes a first dielectric layer on the semiconductor substrate, a first etch-stop layer on the first dielectric layer, and a second dielectric layer on the first etch-stop layer, where the first dielectric layer has a first lateral dimension greater than a second lateral dimension of the second dielectric layer. The metal layer includes a first field plate on at least a first region of the first dielectric layer and a second field plate on at least a second region of the second dielectric layer.

### BACKGROUND

A high electron mobility transistor (HEMT) may include a heterojunction formed using different semiconductor materials, where a channel may be formed near the heterojunction and between a source region and a drain region, and the channel may be turned on or off by applying an appropriate voltage level on a gate structure. Gallium nitride (GaN)-based HEMT devices can have high breakdown field, high electron mobility, low resistance, high current, faster-switching speed, high thermal conductivity, and excellent reverse-recovery performance, and thus may be suitable for applications where a low-loss and high-efficiency performance is desired, such as power electronics, radio frequency (RF) circuits, and the like.

### SUMMARY

This Summary is provided to introduce examples of disclosed concepts in a simplified form, which are further described below in the Detailed Description including the drawings provided.

According to certain aspects, a semiconductor device may include a semiconductor substrate; a source electrode, a gate electrode, and a drain electrode on the semiconductor substrate; a staircase dielectric structure on the semiconductor substrate and laterally between the gate electrode and the drain electrode; and a metal layer on the staircase dielectric structure. The staircase dielectric structure includes a first dielectric layer on the semiconductor substrate, a first etch-stop layer on the first dielectric layer, and a second dielectric layer on the first etch-stop layer, where the first dielectric layer has a first lateral dimension greater than a second lateral dimension of the second dielectric layer. The metal layer includes a first field plate on at least a first region of the first dielectric layer and a second field plate on at least a second region of the second dielectric layer.

According to certain aspects, a method may include depositing a first dielectric layer on a semiconductor device, the semiconductor device including a channel layer and a barrier layer; depositing a first etch-stop layer on the first dielectric layer; depositing a second dielectric layer on the first etch-stop layer; etching selected areas of the second dielectric layer using the first etch-stop layer as the etch stop, the etched second dielectric layer and the first dielectric layer forming a staircase dielectric structure; and depositing a metal layer on the staircase dielectric structure to form a plurality of field plates on the staircase dielectric structure.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative examples are described in detail below with reference to the following figures.

FIG. 1A is a schematic diagram illustrating a cross-sectional view of an example of an enhancement mode high electron mobility transistor (HEMT).

FIG. 1B includes a schematic diagram and a graph illustrating an example of modulating the electric field in the channel layer of the HEMT of FIG. 1A using multiple field plates.

FIG. 2 is a schematic diagram illustrating a cross-sectional view of an example of an HEMT including multiple field plates.

FIG. 3 is a schematic diagram illustrating an example of an HEMT including multiple field plates formed using etch-stop layers.

FIGS. 4A, 4B, 4C, 4D, 4E, 4F, 4G, 4H, 4I, 4J, 4K, and 4L are schematic diagrams illustrating examples of a process of fabricating an HEMT including multiple field plates using etch-stop layers.

FIGS. 5A, 5B, 5C, 5D, 5E, 5F, 5G, and 5H are schematic diagrams illustrating examples of a process of fabricating an HEMT including multiple field plates using etch-stop layers,

FIG. 6 is a schematic diagram illustrating an example of an HEMT including multiple field plates and charged etch-stop layers.

FIG. 7A is a schematic diagram illustrating an example of an HEMT including one or more slanted field plates.

FIG. 7B includes a schematic diagram and a graph illustrating an example of modulating the electric field in the channel layer of the HEMT of FIG. 7A using field plates.

FIGS. 8A, 8B, and 8C are schematic diagrams illustrating examples of capacitors integrated with an HEMT in a semiconductor device.

FIGS. 9A and 9B are schematic diagrams illustrating examples of a planar inductor formed using techniques disclosed herein.

FIG. 10 includes a flowchart illustrating an example of a process of fabricating an HEMT including multiple field plates using one or more etch-stop layers.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative embodiments of the structures and methods illustrated may be employed without departing from the principles, or benefits touted, of this disclosure. Identical reference numerals may be used, where possible, to designate identical elements that are common among drawings. The figures are drawn to clearly illustrate the relevant elements or features and are not necessarily drawn to scale.

### DETAILED DESCRIPTION

The present disclosure relates generally to semiconductor devices and their fabrications. In some examples, a semiconductor device includes a gallium nitride (GaN)-based high electron mobility transistor (HEMT) having multiple field plates fabricated using etch-stop layers. The multiple field plates can reduce the peak electric field in the channel of the HEMT, and thus may improve the off-state breakdown voltage and reduce the dynamic on-state resistance (or current collapse) during high-voltage switching. Precise control of the thickness and uniformity of the thickness of the interlayer dielectric (and thus the field plate height over the channel) can be achieved using one or more etch-stop layers. In some examples, in addition to using the field plate length and height to control the electric field in the channel layer, charges can be introduced onto the etch-stop layers to modify the electron density and electric field in the channel layer, thereby modifying the breakdown voltage and the dynamic on-state resistance during high-voltage switching of the HEMT. In some examples, passive components such as capacitors and inductors with controlled and reproducible dielectric thickness can be integrated with the semiconductor device using fabrication techniques disclosed herein. Other benefits and advantages may also be achieved, such as low process variation, higher yield, high device performance uniformity, and the like.

A GaN-based HEMT may include a heterojunction formed by a channel layer (e.g., a GaN layer) and a barrier layer (e.g., an aluminum gallium nitride (AlGaN) layer). A conductive channel can be formed by high-density two-dimensional electron gas (2DEG) at the heterojunction. For example, the 2DEG can have a sheet charge density greater than about 1013 cm⁻², and thus can have a very low static on-state resistance. GaN-based HEMTs are attractive for high frequency and high power applications due to, for example, the high breakdown field, high electron mobility, low static resistance, and high thermal conductivity of GaN-based HEMTs. In many applications, it may be desirable to use HEMTs with high breakdown voltages and/or low dynamic on-state resistance (or current collapse) during high-voltage switching operations.

When an HEMT is in the off state and has a high drain-to-source voltage, the high electric field in the channel layer (e.g., under the gate, drain contact, and/or field plate) of the HEMT may cause current collapse and even breakdown of the HEMT. Field plates (FPs) can be used in HEMTs to manage the electric field profile between the source and the drain in the off state, thereby increasing the off-state breakdown voltage and reducing the dynamic on-state resistance (or current collapse) during high-voltage switching operations. The FPs and the regions of the HEMT under the FPs may form field plate transistors having different threshold voltages (e.g., different negative pinch-off voltages for turning off the field plate transistors), where the FPs may be the gate electrodes of the field plate transistors. The FPs may be connected to different voltage levels (e.g., the source bias voltage, the gate bias voltage, or another bias voltage level) so that the FPs may turn off the field plate transistors at different regions under different bias conditions, thereby modifying the electric field at the different regions of the channel layer. For example, when the HEMT is in the off state and has a high drain voltage, a field plate on top of the drain side (e.g., the drain-access region) of the channel of the HEMT and connected to the source of the HEMT may turn off the corresponding field plate transistor and thus the conductive channel under the field plate. According, the length of the depleted region of the channel layer that sustains voltage drop and electric field may increase, and thus the peak electric field of the channel layer for a given drain voltage may reduce. By adjusting the lengths and the heights of the field plates, the pinch-off voltages of the field plate transistors may be adjusted, and the electric field distribution between the drain and the gate of the HEMT can be made more uniform, such that the peak electric field of the channel layer under a high drain voltage can be reduced. The reduction of the peak electric field on the gate-to-drain side of the HEMT may result in a higher off-state breakdown voltage.

The reduction of the peak electric field in the channel of the HEMT using FPs may also reduce the hot carrier degradation and dynamic on-state resistance (or current collapse) caused by the high electric field trapping effect. For example, when a lateral HEMT device is in the off-state with a high drain bias, the large negative gate-to-drain bias and thus high electric field can lead to electron injection and trapping at regions such as the heterojunction interface and barrier layer surface. In addition, when the HEMT device operates in high voltages (e.g., a few hundred volts), a hard switching can generate hot electrons in the channel, which may be injected and trapped, for example, in the dielectric, at the surface, in the GaN channel, and/or in the buffer layer. The trapped negative charges may at least partially deplete carriers (e.g., electrons) in the channel, causing a reduction in the channel carrier density and thus an increase in the channel resistance and a reduction in the current between the drain and the source (IDS). When the HEMT device is switched on, it may take a certain amount of time to release the electrons from surface states and buffer traps so that the drain-to-source resistance may gradually decrease and eventually settle at a static on-state resistance. Reducing the peak electric field in the channel of the HEMT may reduce the electron injection and trapping, thereby reducing the dynamic on-state resistance (or current collapse).

Some field plate arrangements (e.g., source-connected field plates and/or gate-connected field plate) may also reduce the gate-to-source capacitance, reduce the gate-to-drain capacitance (e.g., due to the reduced peak electric field), and/or increase the gate conductance. Reducing the capacitances and increasing the gate conductance may lead to increased device gain, bandwidth, and operational frequencies. The reduction of the electric field can also have other benefits, such as reducing leakage currents, reducing time-dependent dielectric breakdown (TDDB) at the gate, and improving reliability.

The electric field distribution between the drain and the gate of the HEMT may depend on, for example, the lengths and the heights of the field plates, and the properties (e.g., permittivity) and the thicknesses of the dielectric layers under the field plates. Integrated passive components such as capacitors and inductors may also need reproducible and more precisely controlled dielectric thickness. However, it can be challenging to achieve good uniformity and precise control of the dielectric thickness of each field plate due to process variations. For example, the field plates may be fabricated using multiple cycles of dielectric and metal deposition and etching, where the etching may have a low selectivity between the metal being etched and the interlayer dielectric (ILD) layer under the metal layer. Therefore, over-etching (e.g., 30-50%) may be performed to ensure complete removal of metals outside the FP area. When over-etching is performed, the heights of the field plates may be difficult to control due to the process variations, and thus the variation in the thickness of the ILD layer may be large. Therefore, the variation in the FP height and thus the pinch-off voltage of the field plate transistor may be large, which can adversely affect the performance of the HEMT, such as the breakdown voltage, off-state leakage, gate-to-drain capacitance, and dynamic on-state resistance (or current collapse). The yield and device performance uniformity across a wafer or between wafers may also be low.

In some examples disclosed herein, a semiconductor device may include a field plate structure formed on a staircase dielectric structure fabricated using etch-stop layers to more precisely control the thicknesses of the interlayer dielectric (ILD) layers. As such, the semiconductor device can have well-controlled thicknesses of the ILD layers between the field plates and the channel layer, and thus may have well-controlled heights of the field plates, well-controlled pinch-off voltages of the field plate transistors, and well-controlled channel electric field modulation and dynamic on-state resistance. In some examples, the etch-stop layers can be charged, where the charge density (or the amount of charging) may be controlled to tune the electric field and electron density of the channel layer, the pinch-off voltages of the field plate transistors and/or the HEMT, and the static on-state resistance and dynamic on-state resistance of the HEMT. Integrated planar inductors and capacitors can also be formed in the semiconductor device using the fabrication processes and the staircase dielectric structure disclosed herein.

In one example, a semiconductor device may include a source electrode, a gate electrode, and a drain electrode on a semiconductor substrate. The semiconductor device may also include a staircase dielectric structure on the semiconductor substrate and laterally between the gate electrode and the drain electrode, and a metal layer on the staircase dielectric structure. The staircase can have steps having upright sidewalls or slanted sidewalls. The staircase dielectric structure may include at least a first dielectric layer on the semiconductor substrate, a first etch-stop layer on the first dielectric layer, and a second dielectric layer on the first etch-stop layer. The first dielectric layer under the second dielectric layer may have a first lateral dimension greater than a second lateral dimension of the second dielectric layer, such that the at least two dielectric layers may form the staircase dielectric structure. The metal layer may form a field plate structure that includes at least a first field plate on at least a first region of the first dielectric layer and a second field plate on at least a second region of the second dielectric layer of the staircase dielectric structure. The first region of the first dielectric layer may have a first uniform thickness, the second region of the second dielectric layer may also have a second uniform thickness, and thus the field plate transistors under the first field plate and the second field plate have different respective pinch-off voltages. In some examples, the first etch-stop layer may include charges stored in or on the first etch-stop layer for tuning the electric field and electron density in the channel of the semiconductor device. In some examples, a sidewall of the second dielectric layer in the staircase dielectric structure may be slanted, such that the field plate structure may also include a slanted field plate between the first field plate and the second field plate. Such arrangements may further reduce the peak electric field in the channel layer and further increase the breakdown voltage of the semiconductor device.

Techniques disclosed herein can achieve controlled thicknesses of ILD layers and controlled heights of field plates, thereby improving the yield and performance uniformity of semiconductor devices having high breakdown voltages, such as GaN-based HEMTs. Multiple field plates with controlled heights and without gaps between the field plates can be fabricated using the techniques disclosed herein to reduce the peak electric field in the channel, reduce the dynamic on-state resistance, and increase the breakdown voltage. In one example, the staircase dielectric structure can be fabricated to have many steps with small step heights to approximate a slope structure, which allows formation of a large number of small field plates on the staircase dielectric structure to approximate a slanted field plate. The etch-stop layers for controlling the thickness of the ILD layers can also store charges, where the charge density (or the total stored charges) may be another parameter for controlling the electric field, the pinch-off voltage, and on-state resistance. Other active or passive devices can also be formed using the ILD layers with uniform thicknesses during the process of fabricating the field plates.

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

Various examples are described herein. Although the specific examples may illustrate various aspects of the above generally described features, examples may incorporate any combination of the above generally described features (which are described in more detail in examples below). Three dimensional x-y-z axes are illustrated in some figures for ease of reference. Some cross-sectional views of various semiconductor devices herein may be general depictions to illustrate various aspects or concepts concerning such semiconductor devices. More specifically, some drain contact structures illustrated in cross-sectional views may not necessarily accurately depict a structure of such drain contact contacts, except to the extent described herein. The illustrations of those drain contact structures are to illustrate various aspects or concepts concerning those drain contact structures.

Various examples are described in the context of an HEMT. Some examples may be implemented in enhancement mode lateral HEMTs that are for high voltage (e.g., about 650 V to about 1,200 V) applications or low to medium voltage (e.g., about 10 V to about 100 V, or about 10 V to about 200 V) applications. In other examples, the semiconductor device may include a bidirectional field effect transistor (FET), a gated Schottky barrier diode (e.g., gate-to-drain shorted structure or gate-to-source shorted structure), or similar devices. Some examples may be implemented with any epitaxial structure, any field plate and/or ohmic contact structure, a planar or three-dimensional structure (e.g., fin structure), and/or various other modifications.

For the sake of illustration, some of the examples disclosed herein may focus on group-III nitride-based devices, such as GaN-based HEMTs. However, this disclosure is not limited to GaN-based HEMTs and can be applied to other devices that include heterostructures formed by other semiconductor materials, such as other group-III nitride or other III-V semiconductor materials, where the heterostructures may induce two-dimensional electron gas (2DEG) at the heterojunction interface.

GaN-based HEMTs may include heterostructures that induce 2DEG at the interface between two GaN-based materials with different bandgaps. In one example, the heterostructure may be formed by a GaN layer and an AlₓGa₍₁₋ₓ₎N layer, where x is the concentration of aluminum. The GaN layer has a narrower bandgap than the AlₓGa₍₁₋ₓ₎N layer, which may function as a barrier layer because of its wider bandgap. Due to the bandgap mismatch, large conduction-band offset, and spontaneous and piezoelectric polarization properties of the group-III nitride layers, highly-mobile 2DEG may be generated in the GaN layer (having the narrower bandgap) near the interface of the heterostructure to form a conductive channel in the GaN layer (which is referred to as the channel layer). Compared to silicon-based transistors, GaN-based transistors devices may have high breakdown field, high electron mobility, low resistance, high current, faster-switching speed, high thermal conductivity, and excellent reverse-recovery performance, and thus may be suitable for applications where a low-loss and high-efficiency performance may be desired, such as power electronics or radio frequency (RF) circuits.

A GaN-based transistor may include a gate structure positioned between a source structure and a drain structure. The drain structure may include a metal contact (e.g., a drain electrode) that is coupled to the channel layer and forms an ohmic contact with the channel layer. The source structure may include a metal contact (e.g., a source electrode) that is coupled to the channel layer and forms an ohmic contact with the channel layer. Depending on the architecture of the gate structure, a GaN-based transistor may be an enhancement mode high electron mobility transistor (e-HEMT) that may be in the off state without a positive gate voltage and may be turned on when a positive voltage is applied to the gate electrode, or may be a depletion mode high electron mobility transistors (d-HEMT) that may be in the on state without a negative gate voltage, and may be turned off when a negative voltage is applied to the gate electrode.

For example, the gate structure of an e-HEMT may include a p-GaN layer formed over the barrier layer and a gate electrical contact (e.g., a metal gate electrode) formed on the p-GaN layer, which together form a p-GaN gate structure. The p-GaN layer may be a GaN layer doped with, for example, magnesium (Mg), which is an acceptor that makes the GaN layer p-type or p-doped. The p-GaN layer may deplete electrons in the 2DEG channel under the p-GaN gate structure, such that the path between the source and drain may be disabled when no gate drive voltage is applied to the gate electrical contact. When a positive voltage above the gate threshold voltage is applied to the gate electrical contact, the gate structure may attract electrons to replete the 2DEG under the gate structure, thereby turning on the e-HEMT.

In contrast, the gate structure of a d-HEMT may include an insulator layer (e.g., a dielectric layer) over the barrier layer and a gate electrical contact (e.g., a metal gate electrode) on the insulator layer. When no voltage signal is applied to the gate electrical contact, the 2DEG under the gate structure may not be depleted, and thus the path in the channel layer between the drain structure and the source structure may be enabled without a positive gate voltage. A d-HEMT can be turned off by applying a negative voltage to the gate electrical contact to deplete electrons from the 2DEG under the gate structure. In some applications such as switch-mode power applications, e-HEMTs, rather than d-HEMTs, may be used in order to, for example, decrease leakage current, reduce power loss, simplify the driving circuit, and/or improve device stability.

GaN-based HEMTs may be attractive for high frequency and high power applications due to, for example, high breakdown voltage, high electron mobility, low static resistance, and high thermal conductivity of GaN-based HEMTs. However, GaN-based HEMTs may suffer from current collapse, which is an undesirable phenomenon of an increase in the dynamic on-state drain-to-source resistance that occurs during high-voltage switching operations, for example, when the GaN-based HEMT is turned on and off and a high voltage level is applied to the drain of the HEMT. Current collapse may result in, for example, power loss, temperature increase, and reliability issues.

Current collapse may be caused by electron and/or hole trapping, and can appear as a transient and recoverable reduction in the drain current (and an increase in the effective resistance) during high-voltage switching operations. Several factors may contribute to current collapse, including electrons trapped at the surface of the barrier layer and/or in the buffer layer, and hot electrons trapped during high voltage switching. For example, for an HEMT including an AlGaN barrier layer and a GaN channel layer, when the HEMT is in the off state and has the following voltage states: a high drain voltage (e.g., a few hundred volts such as about 600V or higher), a gate voltage below the threshold, and a grounded source voltage, high-energy electrons from the 2DEG may be injected towards the top of the AlGaN barrier layer and trapped by the surface states (thereby resulting in a negatively charged surface), due to the high electric field caused by the large negative gate-to-drain bias. The large positive drain-to-substrate voltage may cause electrons to be injected from the substrate and trapped in the buffer stack between the channel layer and the substrate. Furthermore, in the off state, the high electric field induced by the high drain voltage may ionize holes in the heterostructure between the gate and the drain contact structures or underneath the drain contact structure. These ionized holes may be pulled towards the gate and/or source contact structures in the off state due to the electric field caused by the biasing, which may leave fixed negative charges in the heterostructure. When the HEMT operates with high drain voltages (e.g., a few hundred volts), a hard switching can generate hot electrons in the channel due to the high electric field, and the hot electrons may be injected and trapped, for example, in the dielectric, at the surface of the barrier layer, in the channel layer, and/or in the buffer layer. The trapped negative charges and the fixed negative charges in the heterostructure may at least partially deplete carriers (e.g., electrons) in the 2DEG channel, causing a reduction in the channel carrier density and thus an increase in the resistance.

When the HEMT is switched on (e.g., when the gate voltage is above the threshold voltage in an e-HEMT), the dynamic on-state drain-to-source resistance may be high initially as compared to a static on-state drain-to-source resistance, due to the lower channel carrier density resulted from carrier depletion by the negative charges. The trapped electrons and fixed negative charges may be gradually de-trapped when they gain energy to escape the traps, and/or may be gradually neutralized by holes injected from the drain. The remaining negative charges may continue to deplete the 2DEG, leading to a slow reduction of the drain-to-source resistance.

When an HEMT is in the off state, if the drain is biased at a relatively low voltage, the electric field in the channel layer may be low, except in regions near the gate structure where the 2DEG is depleted and the channel is off. Under high drain biases, the electric field in the channel (e.g., at the edge of the gate region) may exceed a threshold field for impact ionization, and thus may generate hot carriers that can degrade the performance of the HEMT. Such energetic carriers can lead to current collapse and even physical failure and permanent damage, such as breakdown of the HEMT, when the electric field in the channel is sufficiently high.

To reduce the current collapse and increase the breakdown voltage, an HEMT may include one or more metal field plates on top of the dielectric layer over the drain-access region. The one or more metal field plates may be connected to, for example, the gate, the source, or another bias voltage level, and thus can be biased to deplete the underlying channel layer when the HEMT is in the off state. In this way, under a similar drain biasing condition, the channel area that sustains electric field and voltage drop may be increased in an HEMT with one or more field plates, and thus the peak electric field in the channel layer of the HEMT can be reduced. Therefore, the HEMT can sustain a higher drain voltage and a higher voltage difference between the drain and the source (VDS), before the peak electric field in the channel layer reaches the threshold field to cause permanent damage to the HEMT. The electric field profile in the channel layer of the HEMT under a given drain bias may depend on the length and height of each field plate. With the length of the field plate increasing, the channel area that sustains electric field and voltage drop may increase, and the peak electric field in the channel layer may decrease. The magnitude of the peak electric field in the channel layer may also be changed by changing the field plate height (e.g., by changing the dielectric thickness). Therefore, a desired electric field profile in the channel layer may be achieved by selecting the appropriate length and height of each of the one or more field plates.

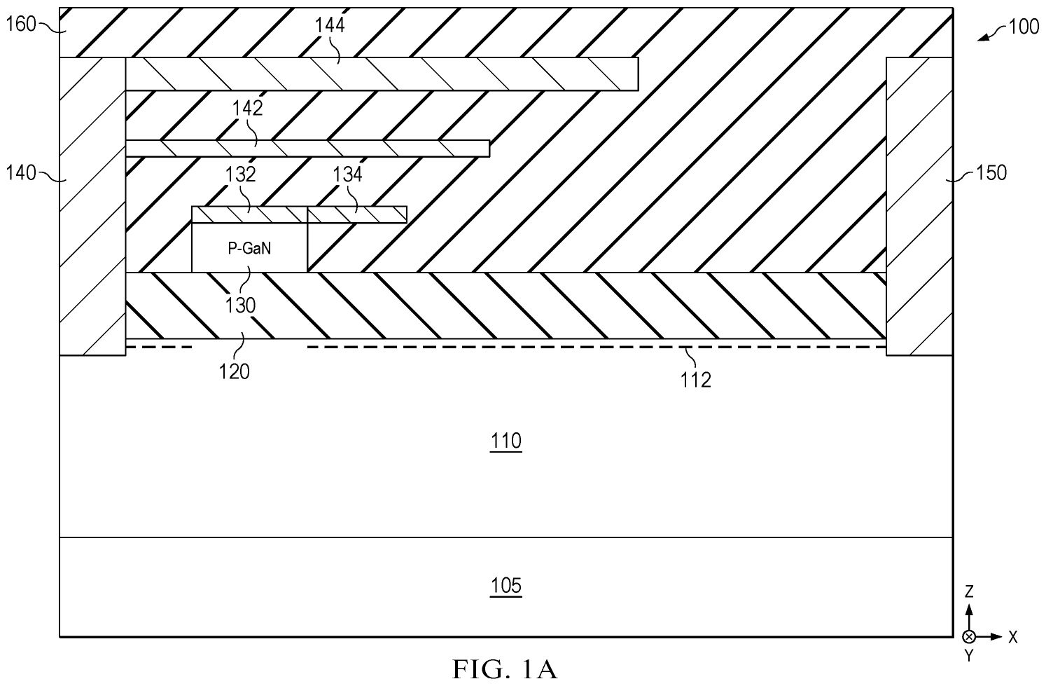

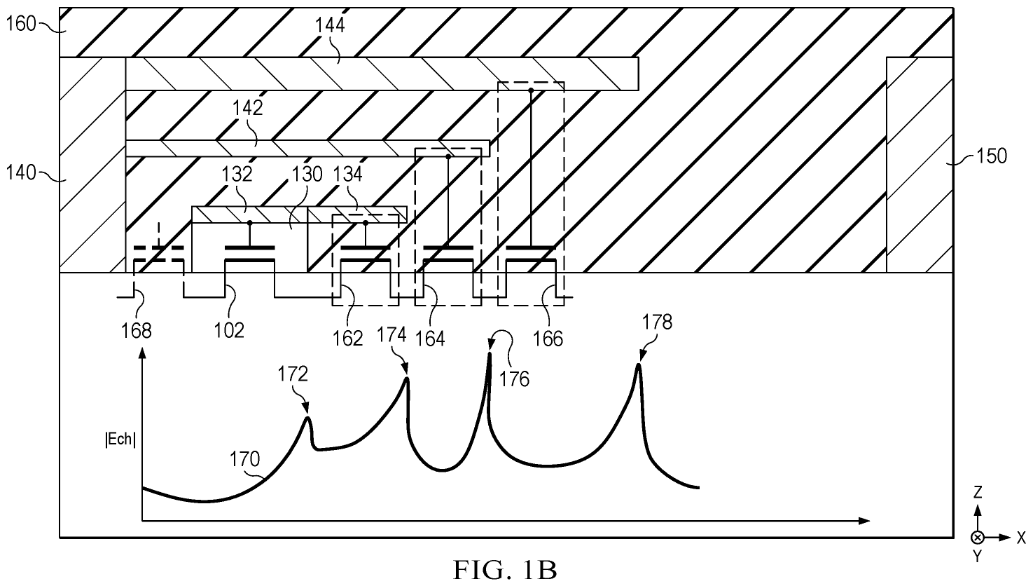

FIG. 1A is a cross-sectional view of an example of an HEMT 100. In the illustrated example, HEMT 100 is an enhancement mode HEMT and includes a substrate 105, a channel layer 110 (e.g., including a GaN layer) grown on substrate 105, a barrier layer 120 (e.g., including an AlGaN layer) over channel layer 110, and drain, source, and gate structures. The drain, source, and gate structures may be electrically isolated by one or more dielectric layers 160. The gate structure is between the drain structure and the source structure, and may be closer to the source structure (e.g., to achieve a high breakdown voltage). In some examples, HEMT 100 shown in FIG. 1A may be a half pitch of an HEMT device that includes HEMT 100 and a mirrored version of HEMT 100 that shares the drain structure with HEMT 100.

Substrate 105 may be a bulk semiconductor substrate, a semiconductor-on-insulator (SOI) substrate, or another suitable substrate (e.g., a Qromis Substrate Technology (QST) substrate, a sapphire substrate, or another silicon-based substrate). In one example, substrate 105 may include a bulk silicon wafer, and one or more transition layers or buffer layers of suitable materials for accommodating the lattice mismatch between substrate 105 and channel layer 110 (e.g., to reduce or minimize lattice defect generation and/or propagation in channel layer 110). For example, the transition layers or buffer layers may have a gradient concentration of one or more elements in a surface normal direction (e.g., z direction) of substrate 105 to gradually change the lattice constant.

Channel layer 110 and barrier layer 120 may be epitaxially grown on substrate 105. Due to the different energy band structures of channel layer 110 and barrier layer 120, a heterostructure may be formed by channel layer 110 and barrier layer 120. The heterostructure may induce a 2DEG 112 near the interface between channel layer 110 and barrier layer 120. 2DEG 112 may conduct current in a two-dimensional plane (e.g., an x-y plane). In some examples, channel layer 110 may be a portion of substrate 105. In the illustrated example, channel layer 110 includes a GaN layer. Channel layer 110 may include an intrinsic material, or an unintentionally doped material, such as a material doped by diffusion of dopants from another layer. In the illustrated example, barrier layer 120 includes an AlGaN layer, which has a wider bandgap than GaN. Other materials may also be used for channel layer 110 and barrier layer 120. For example, channel layer 110 may include indium aluminum gallium nitride (InᵢAlⱼGa₁₋ᵢ₋ⱼN) (where 0≤i≤1, 0≤j≤1, and 0≤i+j≤1), and barrier layer 120 may include indium aluminum gallium nitride (InₖAlₗGa₁₋ₖ₋ₗN) (where 0≤k≤1, 0≤1≤1, and 0≤k+l≤1).

The gate structure of HEMT 100 may include a gate semiconductor layer 130 over an upper surface of barrier layer 120. In some examples, gate semiconductor layer 130 may include a p-doped semiconductor layer. For example, gate semiconductor layer 130 may include a GaN layer, or more generally, an InₘAlₙGa₁₋ₘ₋ₙN layer (where 0≤m<1, 0≤n<1, and 0≤m+n≤1). The p-type dopants for doping gate semiconductor layer 130 may include, for example, magnesium (Mg), carbon (C), zinc (Zn), and the like, or a combination thereof. In some examples, a concentration of the dopant that is electrically activated in gate semiconductor layer 130 may be equal to or greater than about 1×10¹⁷ cm⁻³. In some examples, the concentration may be equal to or greater than about 1×10¹⁸ cm⁻³. Other materials, dopants, and/or concentrations may be used in other examples. Gate semiconductor layer 130 may be formed by epitaxial growth and selective etching using an etch mask, or may be formed by selective area growth using a growth mask. The etch mask or growth mask may define the shape and size of gate semiconductor layer 130. The doping density and thickness of p-doped gate semiconductor layer 130 and the thickness of barrier layer 120 under gate semiconductor layer 130 may be selected such that the p-doped gate semiconductor layer 130 may deplete 2DEG 112 under gate semiconductor layer 130, such that HEMT 100 is off without a positive gate voltage and may be turned on by applying a positive voltage to the gate structure.

A gate electrical contact 132 (e.g., a gate electrode) may be formed on gate semiconductor layer 130 to apply a gate voltage to gate semiconductor layer 130. Gate electrical contact 132 may be electrically connected to a gate drive circuit though electrical interconnects such as conductive traces and/or vias (now shown). In the illustrated example, gate electrical contact 132 may laterally extend beyond gate semiconductor layer 130 to form a field plate 134. Field plate 134 may be used in high voltage and low voltage GaN power devices to, for example, reduce current collapse and dynamic on-state resistance, and increase the breakdown voltage. Gate electrical contact 132 may include one or more metal and/or metal alloy materials having high electrical conductivity. Depending on the metal work function of gate electrical contact 132 and the energy band structure of gate semiconductor layer 130, the metal-to-semiconductor contact between gate electrical contact 132 and gate semiconductor layer 130 may be, for example, an ohmic contact or a Schottky contact having a high or low barrier height. A Schottky contact between gate electrical contact 132 and gate semiconductor layer 130 may reduce gate leakage.

At the source region of HEMT 100, a source electrical contact 140 (e.g., a source electrode) may extend through barrier layer 120 and contact a source region of channel layer 110. In some examples, source electrical contact 140 may not extend into barrier layer 120 and/or channel layer 110, and carriers may tunnel through barrier layer 120 from channel layer 110. In some examples, source electrical contact 140 may be regrown. Source electrical contact 140 may include a metal or metal alloy and may form a low-barrier metal-to-semiconductor contact (e.g., an ohmic contact) with channel layer 110. One or more field plates 142 and 144 may be formed in the one or more dielectric layers 160 and may be coupled to source electrical contact 140 or another voltage bias circuit (e.g., a voltage source). Field plates 142 and 144 may be used to reduce current collapse and dynamic on-state resistance and/or increase the breakdown voltage of HEMT 100.

FIG. 1A shows an example where field plate 134 is connected to gate electrical contact 132 and field plates 142 and 144 are connected to source electrical contact. In other examples not shown in FIG. 1A, the field plates may be biased differently in different examples. In one example, all field plates may be connected to source electrical contact 140. Field plate 134 and field plates 142 and 144 may include a metal or a metal alloy, such as titanium (Ti), titanium tungsten (TiW), titanium nitride (TiN), nickel (Ni), platinum (Pt), tantalum nitride (TaN), copper (Cu), tungsten (W), gold (Au), aluminum (Al), titanium tungsten aluminum (TiWAl), titanium aluminum nitride (TiAlN), or a combination thereof.

At the drain region of HEMT 100, a drain electrical contact 150 (e.g., a drain electrode) may extend through dielectric layer 160 and barrier layer 120 and may contact a drain region of channel layer 110. In some examples, drain electrical contact 150 may not extend into barrier layer 120 and/or channel layer 110, and carriers may tunnel through barrier layer 120. In some examples, drain electrical contact 150 may be regrown. Drain electrical contact 150 may include a metal or metal alloy and may form a low-barrier metal-to-semiconductor contact (e.g., an ohmic contact) with channel layer 110. A described above, in some examples, HEMT 100 shown in FIG. 1A may be a half pitch of an HEMT device that includes HEMT 100 and a mirrored version of HEMT 100 that shares drain electrical contact 150 with HEMT 100.

The one or more dielectric layers 160 may include one or more dielectric materials that isolate and protect the gate structure, drain structure, and source structure. The one or more dielectric layers 160 may include multiple dielectric layers of a same dielectric material or different dielectric materials deposited in one or more deposition processes. For example, dielectric layer 160 may include an oxide-based material or a nitride-based material, such as silicon oxide (e.g., a phosphosilicate glass (PSG)), aluminum oxide, silicon nitride, silicon oxynitride (SiON), and the like. In some examples, dielectric layer 160 may further include one or more etch-stop layers, such as silicon nitride (SiN), aluminum oxide, and the like, for controlling the etch depth of the etching processes (e.g., for patterning a dielectric or metal layer).

In some examples, the electrical contacts or other metal electrical interconnects described above may each include one or more adhesion layers (e.g., Ti) and/or one or more metal barrier layers (e.g., TiN, TaN, etc.) between the metal material (e.g., Al, Cu, W, the like, or a combination thereof) and the dielectric material(s) of the one or more dielectric layers 160. The one or more metal barrier layers may prevent the diffusion of metal atoms into dielectric layers 160. The one or more adhesion layers may be used to improve the adhesion of the metal material to the dielectric material(s) of dielectric layers 160 to reduce or avoid defects and reliability issues such as interfacial delamination.

FIG. 1B illustrates an example of modulating the electric field in the channel layer of HEMT 100 of FIG. 1A using multiple field plates. As illustrated, HEMT 100 may include a core transistor 102 at the gate region, which may be off when the bias voltage at the gate is lower than the gate threshold voltage. HEMT 100 may also include multiple field plate transistors in regions under the field plates. For example, a first field plate transistor 162 may be formed under field plate 134, a second field plate transistor 164 may be formed under field plate 142, and a third field plate transistor 166 may be formed under field plate 144. The field plates may function as the gates of the field plate transistors. The threshold voltages (e.g., pinch-off voltages) of first field plate transistor 162, second field plate transistor 164, and third field plate transistor 166 may depend on, for example, the heights of the field plates over channel layer 110 and the material of dielectric layers 160. Therefore, the field plates with different heights may have different threshold voltages and may be turned on or off under different bias conditions.

In one example, the field plates may be biased such that, when the gate of HEMT 100 is biased at a voltage below the threshold voltage and the drain of HEMT 100 is biased at a relatively low voltage, core transistor 102 may be in the off state and the field plate transistors may be in the on state. Under this condition, core transistor 102 may sustain the voltage drop between the drain and the source and thus the electric field in the channel layer, whereas the field plate transistors may sustain little or no voltage drop and electric field. Therefore, the electric field in the channel layer may peak at the edge of the gate of HEMT 100 (e.g., the drain of core transistor 102) and may decrease in a direction towards the drain region (e.g., along the x direction).

As the bias voltage at the drain increases, the voltage level at the edge of the gate of HEMT 100 (e.g., the drain of core transistor 102) may increase, and thus the voltage difference between the gate (e.g., field plate 134) and the source (e.g., the drain of core transistor 102) of first field plate transistor 162 may be lower than the negative pinch-off voltage of first field plate transistor 162. Therefore, first field plate transistor 162 may also be turned off to sustain a voltage drop and electric field between the drain and source of first field plate transistor 162. The electric field in the channel layer under this condition may have another peak at the edge of field plate 134 and may gradually decrease along the x direction.

As the bias voltage at the drain further increases, the voltage level at the edge of field plate 134 (e.g., the drain of first field plate transistor 162) may increase, and thus the voltage difference between the gate (e.g., field plate 142) and the source (e.g., the drain of first field plate transistor 162) of second field plate transistor 164 may be lower than the negative pinch-off voltage of second field plate transistor 164. Therefore, second field plate transistor 164 may also be turned off to sustain a voltage difference and the corresponding electric field between the drain and source of second field plate transistor 164. The electric field in the channel layer under this condition may have yet another peak at the edge of field plate 142 (e.g., the drain of second field plate transistor 164) and may gradually decrease along the x direction.

As the bias voltage at the drain increases even more, the voltage level at the edge of field plate 142 may increase, and thus the voltage difference between the gate (e.g., field plate 144) and the source (e.g., the drain of second field plate transistor 164) of third field plate transistor 166 may be lower than the negative pinch-off voltage of third field plate transistor 166. Therefore, third field plate transistor 166 may also be turned off to sustain a voltage difference and the corresponding electric field between the drain and source of third field plate transistor 166. The electric field in the channel layer under this condition may have yet another peak at the edge of field plate 144 and may gradually decrease along the x direction. In this way, the channel layer may be able to sustain a large total voltage drop between the drain and the source before the peak electric field in the channel layer reaches a threshold value to cause impact ionization, hot carrier generation, current collapse, and breakdown of HEMT 100.

As shown in FIG. 1B, when a field plate (e.g., field plate 142) is over the region between the gate and the source, a fourth field plate transistor 168 may also be formed under field plate 142. Fourth field plate transistor 168 may also be able to sustain a voltage drop and an electric field between its drain and source when HEMT 100 is in the off state, to further increase the breakdown voltage of HEMT 100.

A graph 170 in FIG. 1B shows an example of the distribution of the electric field in the channel layer of HEMT 100 when HEMT 100 is in the off state and the drain voltage is high. In the example shown by graph 170 of FIG. 1B, the three field plates in the drain-access region may have discontinuities in between and thus may have gaps in the pinch-off voltages as well. The electric field in the channel layer of HEMT 100 may have a first peak 172 near the edge of the gate of HEMT 100 (e.g., edge of gate semiconductor layer 130), a second peak 174 near the edge of field plate 134, a third peak 176 near the edge of field plate 142, and a fourth peak 178 near the edge of field plate 144. The total area under graph 170 may represent the voltage difference between the drain and source (VDS) of HEMT 100. Without field plates 134, 142, and 144, most of the voltage difference between the drain and source (VDs) may be sustained by core transistor 102, and the peak electric field may be at the edge of the gate of HEMT 100 (e.g., edge of gate semiconductor layer 130) and may be high when VDs is large. With field plates 134, 142, and 144, the voltage difference between the drain and source (VDS) may be sustained by core transistor 102 and field plate transistors 162, 164, and 166, and thus the peak electric field can be reduced significantly under the same bias condition. As such, current collapse can be reduced and the breakdown voltage can be increased in HEMT 100.

As described above, the electric field in the channel layer may be tuned by changing, for example, the lengths and heights of the field plates. Therefore, a desired electric field profile in the channel layer under a high drain voltage condition may be achieved by selecting appropriate lengths and heights of the field plates. The field plates can be used to reduce the peak electric field in both e-HEMTs and d-HEMTs. Some field plate arrangements, such as source-connected field plates and/or gate-connected field plate, can reduce the gate-to-source capacitance, reduce the gate-to-drain capacitance (e.g., due to the reduced peak electric field in the drain-access region), and/or increase gate conductance. Reducing the capacitances and increasing the gate conductance may lead to increased device gain, bandwidth and operational frequencies. The reduction of the electric field can also have other benefits, such as reducing leakage currents, reducing time-dependent dielectric breakdown (TDDB) at the gate, and improving reliability.

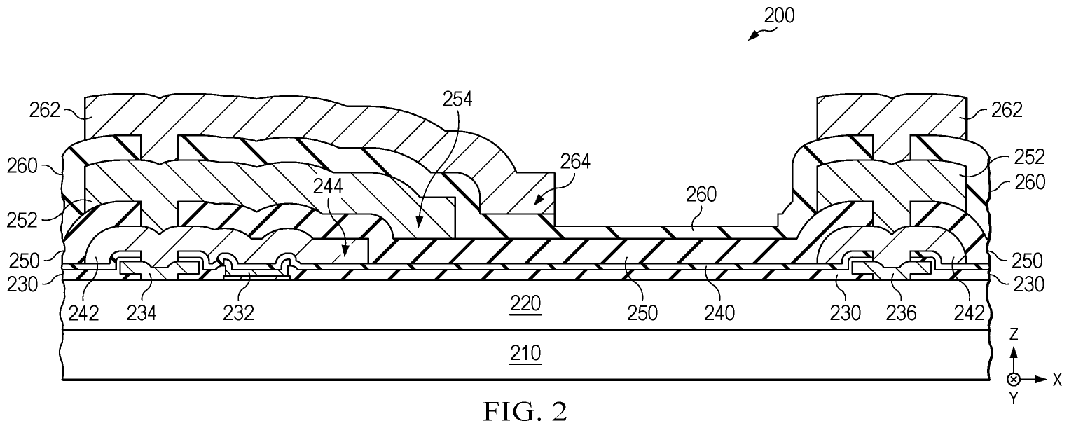

FIG. 2 is a cross-sectional view of an example of an HEMT 200 including multiple source-connected field plates. HEMT 200 may be an example of an implementation of HEMT 100, and may be an e-HEMT or a d-HEMT. In the illustrated example, HEMT 200 may include a substrate 210, epitaxial layers 220 grown on substrate 210, and a gate structure 232, a source structure 234, and a drain structure 236 formed on epitaxial layers 220. Multiple dielectric layers may be deposited and patterned, and multiple metal layers may be formed on respective dielectric layers and patterned to form multiple field plates. The dielectric layers may include, for example, SiO₂, SiNₓ, or Al₂O₃ layers. The metal layers may include, for example, Cu, Al, W, Ti, Au, Ni, Pt, TiW, TiN, TaN, TiWAl, TiAlN, or a combination thereof. In the example shown in FIG. 2, the field plates may be connected to the source electrical contact. In other examples, the field plates may be connected to the gate electrical contact, the source electrical contact, other voltage sources, or a combination thereof.

Substrate 210 may be similar to substrate 105 of HEMT 100. Epitaxial layers 220 may include, for example, a channel layer and a barrier layer, such as channel layer 110 and barrier layer 120. Gate structure 232 may include a gate electrical contact, and a semiconductor layer (e.g., a p-doped GaN layer) or a dielectric layer. A first dielectric layer 230 may be formed on epitaxial layers 220, and may be patterned to define the gate region, source region, and drain region. A metal or metal alloy material may be deposited in the gate region, source region, and drain region, to form the gate electrical contact, source electrical contact, and drain electrical contact.

A second dielectric layer 240 may be deposited on first dielectric layer 230, gate electrical contact, source electrical contact, and drain electrical contact. In some examples, second dielectric layer 240 may be etched at the source region and the drain region to expose the source electrical contact and drain electrical contact. A first metal layer 242 may then be formed (e.g., by sputtering) on second dielectric layer 240. Some regions of first metal layer 242 between the gate region and the drain region may be removed by etching. In order to fully remove the metal material in these regions, first metal layer 242 may be over-etched (e.g., about 30-50% over-etching) into the underlying second dielectric layer 240. Due to process variations, the amount of over-etching may vary across a wafer and may also vary wafer-to-wafer or lot-to-lot. Therefore, the thickness of the remaining second dielectric layer 240 may vary across a wafer and may also vary wafer-to-wafer or lot-to-lot. A portion 244 of first metal layer 242 may remain in regions between the gate and the drain, and may be used as a first field plate.

A third dielectric layer 250 may then be formed on the remaining first metal layer 242 and the exposed second dielectric layer 240. In some examples, third dielectric layer 250 may be etched at the source region and the drain region to expose the metal electrical contacts at the source and drain. A second metal layer 252 may then be formed on third dielectric layer 250. Some regions of second metal layer 252 between the gate region and the drain region may be removed by etching. In order to fully remove the metal material in these regions, second metal layer 252 may be over-etched into the underlying third dielectric layer 250. Due to process variations, the amount of over-etching may vary across a wafer and may also vary wafer-to-wafer or lot-to-lot. Therefore, the thickness of the remaining third dielectric layer 250 may vary across a wafer and may also vary wafer-to-wafer or lot-to-lot. A portion 254 of second metal layer 252 may remain in regions between the gate and the drain, and may be used as a second field plate. As shown in FIG. 2, because the process of over-etching into second dielectric layer 240 may be difficult to precisely control, the thickness of the remaining second dielectric layer 240 and the total thickness of the dielectric material under portion 254 (the second field plate) of second metal layer 252 may be difficult to control. Therefore, the height of the second field plate may vary from device to device, and the threshold voltage of the field plate transistor formed under the second field plate may vary from device to device.

FIG. 2 also shows that a fourth dielectric layer 260 may be formed on the remaining second metal layer 252 and the exposed third dielectric layer 250. In some examples, fourth dielectric layer 260 may be etched at the source region and the drain region to expose the metal electrical contacts at the source and drain. A third metal layer 262 may then be formed on fourth dielectric layer 260. Some regions of third metal layer 262 between the gate region and the drain region may be removed by etching. In order to fully remove the metal material in these regions, third metal layer 262 may be over-etched into the underlying fourth dielectric layer 260. However, due to process variations, the amount of over-etching may vary across a wafer and may also vary wafer-to-wafer or lot-to-lot. Therefore, the thickness of the remaining fourth dielectric layer 260 may vary across a wafer and may also vary wafer-to-wafer or lot-to-lot. A portion 264 of third metal layer 262 may remain in regions between the gate and the drain, and may be used as a third field plate. As shown in FIG. 2, because the process of over-etching into third dielectric layer 250 may be difficult to precisely control, the thickness of the remaining third dielectric layer 250 and the total thickness of the dielectric material under portion 264 (the third field plate) of third metal layer 262 may be difficult to control. Therefore, the height of the third field plate may vary from device to device, and the threshold voltage of the field plate transistor formed under the third field plate may vary from device to device.

Additional field plates may be formed using additional cycles of dielectric and metal deposition and etching to tune the electric field in the channel layer of HEMT 200. However, as shown in FIG. 2 and described above, the etching may have a low selectivity between the metal being etched and the underlying dielectric layer. Therefore, over-etching (e.g., 30-50%) may be performed to ensure complete removal of metals outside the field plate area. But the heights of the field plates may be difficult to control due to process variations when over-etching is performed, and the variation in the thickness of the interlayer dielectric (ILD) layer and the threshold voltage of the field plate transistor may be large, which can adversely affect the yield and uniformity of the performance of the HEMT, such as the breakdown voltage, off-state leakage, and dynamic on-resistance or current collapse. Thus, it can be challenging to achieve good uniformity and precise control of the dielectric thickness of each field plate and thus the threshold voltage (e.g., the pinch-off voltage) of the corresponding field plate transistor formed under the field plate.

According to some examples disclosed herein, a semiconductor device may include a field plate structure formed on a staircase dielectric structure fabricated using etch-stop layers to more precisely control the thicknesses of the interlayer dielectric (ILD) layers. As such, the semiconductor device can have well-controlled thicknesses of the ILD layers between the field plates and the channel layer, and thus may have well-controlled heights of the field plates, well-controlled pinch-off voltages of the field plate transistors, and well-controlled channel electric field modulation and dynamic on-state resistance. In some examples, the etch-stop layers can be charged, where the charge density (or the amount of charging) may be used as another parameter (in additional to the field plate length and heigh) to tune the electric field and electron density of the channel layer, the pinch-off voltages of the field plate transistors and/or the HEMT, and the static on-state resistance and dynamic on-state resistance of the HEMT. Integrated planar inductors and capacitors can also be formed in the semiconductor device using the fabrication processes and the staircase dielectric structure with more precisely controlled interlayer dielectric thickness.

FIG. 3 illustrates an example of an HEMT 300 including multiple field plates and etch-stop layers. HEMT 300 may be another example of an implementation of HEMT 100, and may be an e-HEMT or a d-HEMT. In the illustrated example, HEMT 300 may include a substrate 310, epitaxial layers 320 grown on substrate 310, and a gate structure 332, a source structure 334, and a drain structure 336 formed on epitaxial layers 320. Multiple dielectric layers may be deposited and patterned (e.g., etched using etch-stop layers) to form a staircase dielectric structure in the drain-access region between the drain and gate. The dielectric layers may include, for example, SiO₂, SiNₓ, or Al₂O₃ layers. The etch-stop layers may include, for example, a dielectric material, a piezoelectric material, a semiconductor material, polysilicon, or a combination thereof. In some examples, one or more of the etch-stop layers may be charged. The staircase dielectric structure may include a plurality of planar steps with well-controlled heights. One or more metal layers may be formed on the staircase dielectric structure to form multiple field plates with different heights. The metal layers may include, for example, Cu, Al, W, Ti, Au, Ni, Pt, TiW, TiN, TaN, TiWAl, TiAlN, or a combination thereof. In the example shown in FIG. 3, the field plates may be connected to the source electrical contact. In other examples, the field plates may be connected to the gate electrical contact, the source electrical contact, other voltage sources, or a combination thereof.

Substrate 310 may be similar to substrate 105 of HEMT 100. Epitaxial layers 320 may include, for example, a channel layer and a barrier layer, such as channel layer 110 and barrier layer 120. Gate structure 332 may include a gate electrical contact, and a semiconductor layer (e.g., a p-doped GaN layer) or a dielectric layer. In one example, a first dielectric layer 330 may be formed on epitaxial layers 320, and may be patterned to define the gate region, source region, and drain region. A metal or metal alloy material may be deposited in the gate region, source region, and drain region, to form the gate electrical contact, source electrical contact, and drain electrical contact.

A second dielectric layer 340 may be deposited on first dielectric layer 330, gate electrical contact, source electrical contact, and drain electrical contact. In some examples, second dielectric layer 340 may be etch at the source region and the drain region to expose the source electrical contact and drain electrical contact. A first etch-stop layer 342 may be formed on second dielectric layer 340 and the exposed drain contact and source contact. First etch-stop layer 342 and the dielectric layers (e.g., second dielectric layer 340 and first dielectric layer 330) may have different etch rates under a same dry or wet etching condition. For example, under one etching condition, the dielectric layers may be etched at an etch rate much higher than the etch rate of the etch-stop layer. Under another etching condition, the dielectric layers may be etched at an etch rate much lower than the etch rate of the etch-stop layer. As described above, first etch-stop layer 342 may include, for example, a dielectric material, a piezoelectric material, a semiconductor material, polysilicon, or a combination thereof. In one example, the dielectric layers may include SiN, and first etch-stop layer 342 may include Al₂O₃. In some examples, first etch-stop layer 342 may be charged as described in more detail below.

A third dielectric layer 350 may be formed on first etch-stop layer 342, and may then be patterned by etching to remove third dielectric layer 350 in the drain region, the source region, and at least a region between the drain and gate. The etching may use a first etching recipe that may have a higher etch rate for third dielectric layer 350, but may have a low etch rate for first etch-stop layer 342. Due to the low etch rate of the underlying first etch-stop layer 342, the etching may stop at first etch-stop layer 342 even when over-etching is performed to fully remove regions of third dielectric layer 350. Optionally, the exposed regions of first etch-stop layer 342 may be etched using a second etching recipe that may have a high etch rate for first etch-stop layer 342, but may have a low etch rate for second dielectric layer 340. Therefore, the exposed regions of first etch-stop layer 342 may be etched by over-etching, with little or no etching of second dielectric layer 340.

A second etch-stop layer 352 may be formed on third dielectric layer 350 and the exposed drain contact and source contact. Second etch-stop layer 352 may be similar to or different from first etch-stop layer 342, and may have an etch rate different from the etch rate of the dielectric layers (e.g., third dielectric layer 350) under a same dry or wet etching condition. In some examples, second etch-stop layer 352 may be charged as described in more detail below. In some examples, second etch-stop layer 352 and first etch stop layer 342 may have different numbers and/or polarities of charges. A fourth dielectric layer 360 may be formed on second etch-stop layer 352, and may then be patterned by etching to remove fourth dielectric layer 360 in the drain region, the source region, and at least a region between the drain and gate. The etching may use an etching recipe that may have a higher etch rate for fourth dielectric layer 360, but may have a low etch rate for second etch-stop layer 352. Due to the low etch rate of the underlying second etch-stop layer 352, the etching may stop at second etch-stop layer 352 even when over-etching is performed to fully remove regions of fourth dielectric layer 360. Optionally, the exposed regions of second etch-stop layer 352 may be etched using another etching recipe that may have a high etch rate for second etch-stop layer 352, but may have a low etch rate for third dielectric layer 350. Therefore, the exposed regions of second etch-stop layer 352 may be fully etched by over-etching, with little or no etching of the underlying third dielectric layer 350.

In the illustrated example, the staircase dielectric structure may have at least three steps, and each of the three steps may have a uniform height. Additional etch-stop layers and patterned dielectric layers may be formed using additional cycles of deposition and etching of the etch-stop layer and dielectric layer as described above to form additional steps of the staircase dielectric structure. In this process flow, the etching can be more precisely controlled to avoid etching into the underlying material layer, and the thickness of each of the remaining dielectric layers may be close to the thickness of the dielectric layer as deposited. As such, the thickness of each step (e.g., the rise) of the staircase dielectric structure and thus the height of each field plate formed on the staircase dielectric structure can be more precisely and reproducibly controlled even with process variations.

After the formation of the staircase dielectric structure, a metal layer 370 may be formed on the staircase dielectric structure and the exposed drain contact and source contact. In some examples, some regions of metal layer 370 (e.g., regions close to the drain) may be removed by etching. In the illustrated example, metal layer 370 may form three field plates on the staircase dielectric structure, such as a first field plate 372, a second field plate 374, and a third field plate 376. The three field plates have different heights, and thus the corresponding field plate transistors may have different threshold voltages (e.g., pinch-off voltages). A desired electric field profile in the channel layer of HEMT 300 may be achieved by selecting the appropriate heights and lengths of the field plates and the charges introduced onto the etch-stop layers and/or dielectric layers.

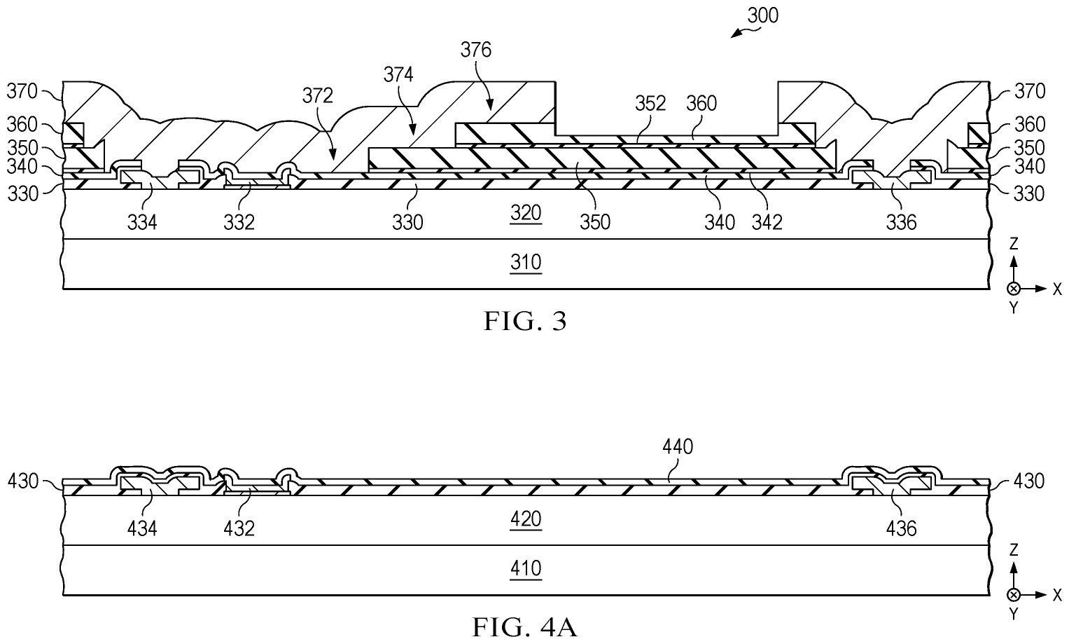

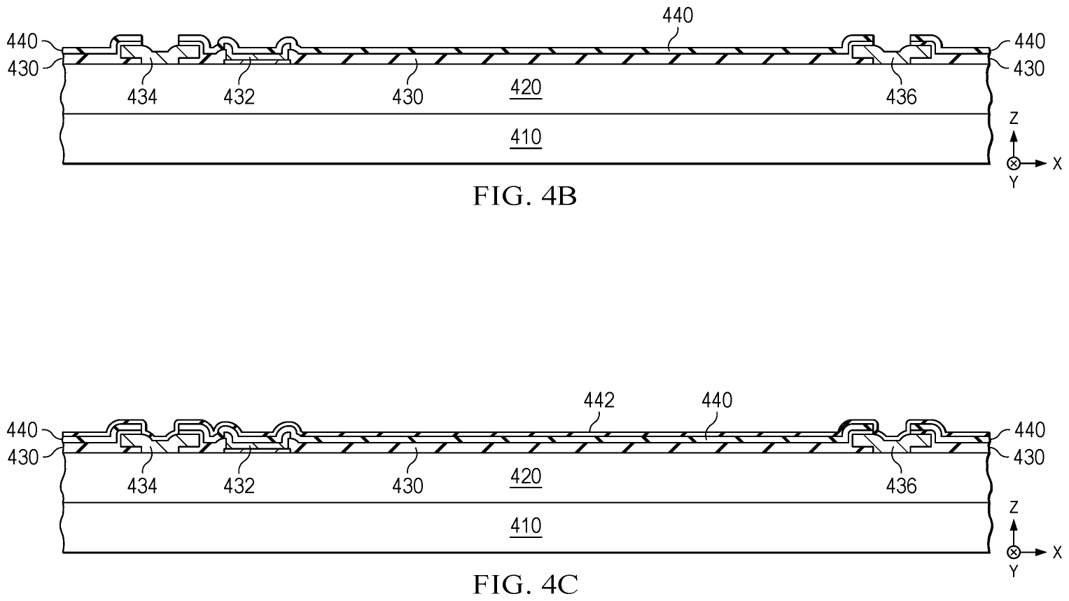

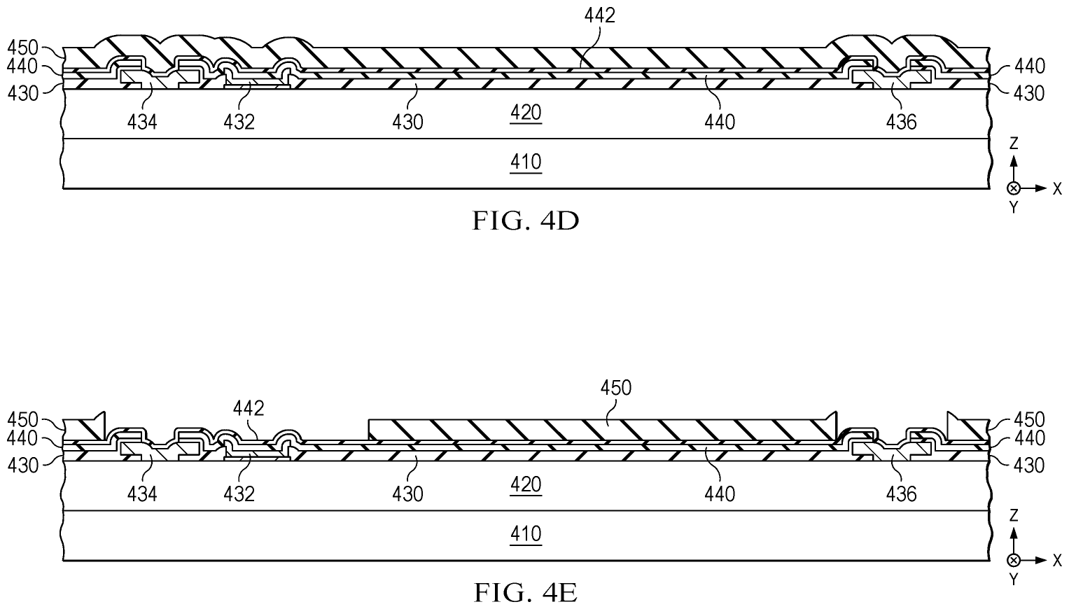

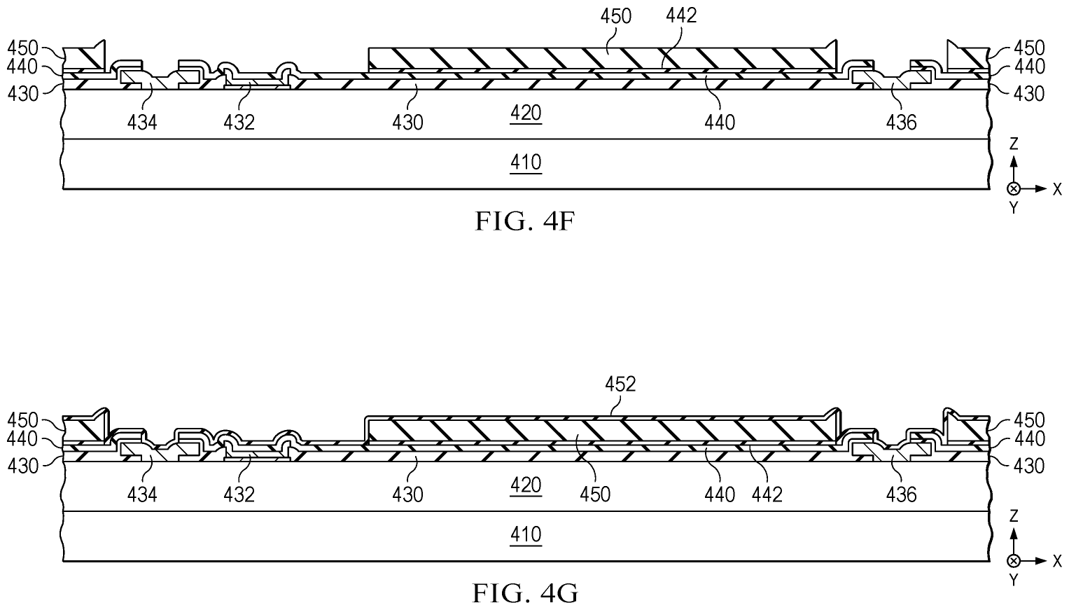

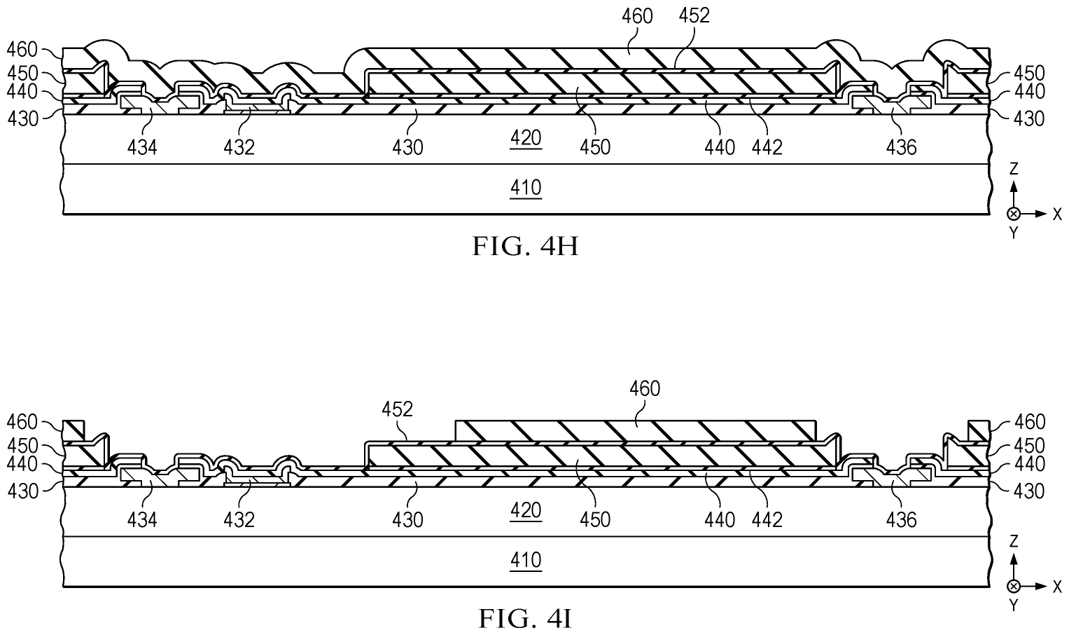

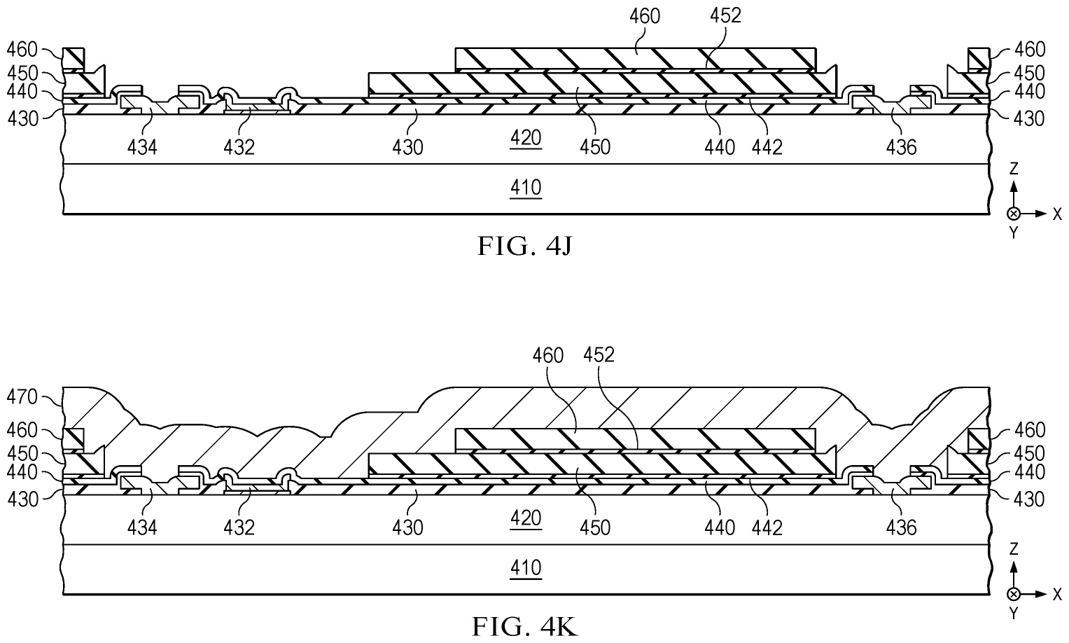

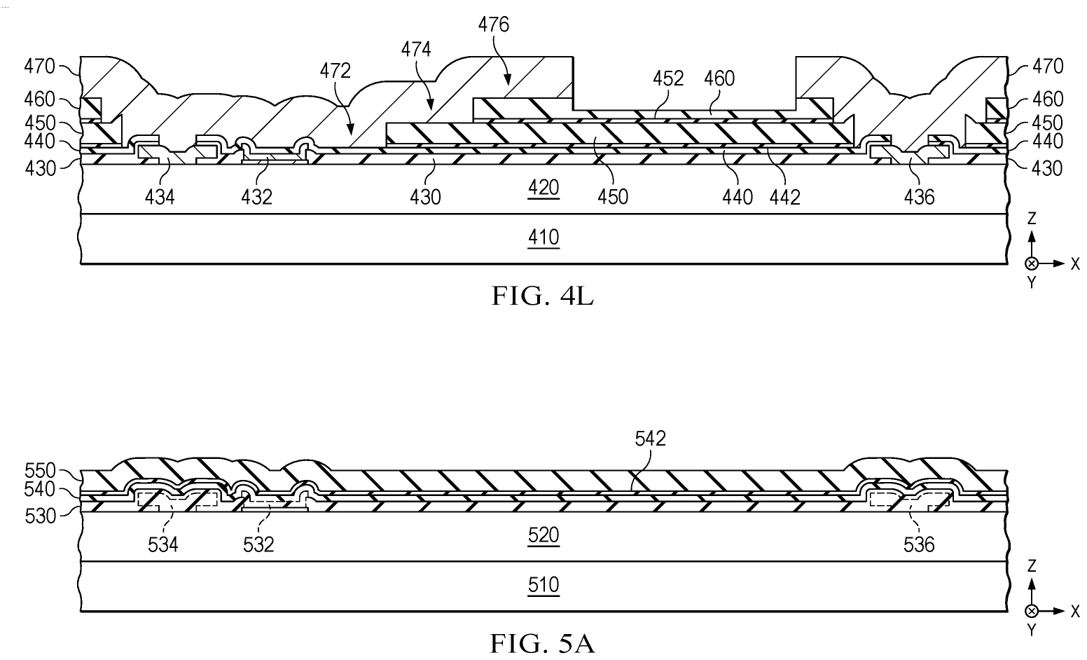

FIGS. 4A, 4B, 4C, 4D, 4E, 4F, 4G, 4H, 4I, 4J, 4K, and 4L illustrate an example of a process of fabricating an HEMT (e.g., HEMT 300) including multiple field plates using etch-stop layers. FIG. 4A shows a semiconductor wafer including a substrate 410, epitaxial layers 420 on substrate 410, and a gate structure 432, a source structure 434, and a drain structure 436 formed on epitaxial layers 420. As described above, substrate 410 may be a bulk semiconductor substrate, a semiconductor-on-insulator (SOI) substrate, or any other suitable substrate (e.g., a QST substrate, a sapphire substrate, or another silicon-based substrate). In one example, substrate 410 may include a bulk silicon wafer, and may include one or more transition layers or buffer layers of suitable materials for accommodating the lattice mismatch between substrate 410 and epitaxial layers 420 (e.g., to reduce or minimize lattice defect generation and/or propagation). For example, the transition layers or buffer layers may have a gradient concentration of one or more elements in a surface normal direction of substrate 410 (e.g., z direction) to gradually change the lattice constant.

Epitaxial layers 420 may include, for example, a channel layer and a barrier layer that form a heterostructure that may induce a 2DEG near the interface between the channel layer and the barrier layer, due to the different energy band structures of the channel layer and the barrier layer. The 2DEG may conduct current in a two-dimensional plane (e.g., an x-y plane). In some examples, the channel layer may include a GaN layer. In some examples, the channel layer may include an unintentionally doped material, such as a material doped by diffusion of dopants from another layer, or may include an intrinsic material. In some examples, the barrier layer may include an AlGaN layer, which has a wider bandgap than GaN. Other materials may also be used for the channel layer and the barrier layer.

Gate structure 432 may include a gate semiconductor layer or a gate dielectric layer over an upper surface of the barrier layer of epitaxial layers 420, and may also include a gate electrical contact (e.g., a gate electrode). Gate structure 432 with the gate semiconductor layer may be used to form an e-HEMT, and gate structure 432 with a gate dielectric layer may be used to form a d-HEMT. In some examples, the gate semiconductor layer may include a p-doped semiconductor layer, such as a p-doped GaN layer as described above with respect to FIG. 1A. In one example, the p-doped GaN layer at gate structure 432 may be formed by epitaxial growth on epitaxial layers 420 followed by selective area etching to remove the p-doped GaN layer in other regions. In another example, the p-doped GaN layer at gate structure 432 may be formed by depositing and patterning a dielectric layer 430 to expose epitaxial layers 420 at the gate region, followed by selective area growth of p-doped GaN on the exposed epitaxial layer 420.

Dielectric layer 430 may be deposited before or after forming the gate semiconductor layer or the gate dielectric layer. Dielectric layer 430 may include, for example, an oxide-based material or a nitride-based material, such as silicon oxide (e.g., PSG), aluminum oxide, silicon nitride, and the like. Dielectric layer 430 may be patterned to expose epitaxial layers 420 at the drain region and the source region, and the gate semiconductor layer or gate dielectric layer. A metal layer may be deposited onto the exposed regions by, for example, metal sputtering, and etching and/or planarization. The deposited metal layer may form gate electrical contact, source electrical contact, and drain electrical contact. In some examples, gate electrical contact, source electrical contact, and drain electrical contact may be formed on epitaxial layers 420 before depositing dielectric layer 430. A dielectric layer 440 may be deposited on the semiconductor wafer to cover the gate electrical contact, source electrical contact, and drain electrical contact. The thickness of dielectric layer 440 may be determined based on the desired height of a first field plate, and may be controlled by, for example, controlling the deposition rate and deposition time.

FIG. 4B shows that dielectric layer 440 at the drain region and the source region may be removed (e.g., by selective etching using an etch mask) to expose the drain electrical contact and the source electrical contact. An etch-stop layer 442 may then be deposited or grown on the semiconductor wafer as shown in FIG. 4C. Etch-stop layer 442 may have an etch rate different from the etch rate of dielectric layer 440. Etch-stop layer 442 may include, for example, a dielectric material, a piezoelectric material, a semiconductor material, polysilicon, or a combination thereof. In one example, dielectric layer 440 may include SiNₓ, and etch-stop layer 442 may include Al₂O₃. Dielectric layer 440 and etch-stop layer 442 may be formed using any suitable techniques, such as ion-beam deposition, chemical vapor deposition (CVD), physical vapor deposition (PVD), plasma-enhanced chemical vapor deposition (PECVD), low pressure chemical vapor deposition (LPCVD), atomic-layer deposition (ALD), sputtering, and the like.

In FIG. 4D, a dielectric layer 450 with a desired thickness may be formed on etch-stop layer 442. Dielectric layer 450 may include a dielectric material that is the same as or different from the dielectric material of dielectric layer 440, and may be formed using any suitable techniques, such as the deposition techniques described above. The thickness of dielectric layer 450 may be determined based on the desired height of a second field plate, and may be controlled by, for example, controlling the deposition rate and deposition time. Dielectric layer 450 may be conformally deposited on the semiconductor wafer, and may or may not have a flat top surface after the deposition.

FIG. 4E shows that dielectric layer 450 at selected regions, such as the gate region, source region, drain region, and a portion of the drain-access region, may be removed by, for example, dry or wet etching. The etching may have a high selectivity, and may have a high etch rate for the dielectric material in dielectric layer 450 and a very low etch rate for the material of etch-stop layer 442. An etch mask may be used to define the areas for etching. The etch time may be sufficiently long to fully remove dielectric layer 450 at the selected area. Due to the low etch rate of the underlying etch-stop layer 442, over-etching may not etch into dielectric layer 440.

Optionally, in FIG. 4F, regions of etch-stop layer 442 exposed after the dielectric etching may be completely or partially removed using another etching process and the same etch mask. The etching process may be different from the etching process for etching dielectric layer 450, and may have an etch selectivity that preferentially etches etch-stop layer 442 and have a low etch rate for the dielectric material of the underlying dielectric layer 440. Therefore, the etch time can be sufficiently long to fully remove etch-stop layer 442 at the exposed area, without etching into dielectric layer 440.

FIG. 4G shows that an etch-stop layer 452 may be conformally formed on top of the semiconductor wafer. Etch-stop layer 452 may be similar to etch-stop layer 442, and may be formed using, for example, deposition techniques described above. A dielectric layer 460 with a desired thickness may then be formed on etch-stop layer 452 as shown in FIG. 4H. Dielectric layer 460 may include a dielectric material that is the same as or different from the dielectric material of dielectric layer 450, and may be formed using any suitable techniques, such as the deposition techniques described above. The thickness of dielectric layer 460 may be determined based on the desired height of a third field plate, and may be controlled by, for example, controlling the deposition rate and deposition time. Dielectric layer 460 may be conformally deposited on the semiconductor wafer, and may or may not have a flat top surface after the deposition.

FIG. 4I shows that dielectric layer 460 at selected regions, such as the gate region, source region, drain region, and some portions of the drain-access region, may be removed by, for example, dry or wet etching. The etching may have a high selectivity, such as a high etch rate for the dielectric material in dielectric layer 460 and a much lower etch rate for the material of etch-stop layer 452. An etch mask may be used to define the selected regions for etching. The etch time may be sufficiently long to fully remove dielectric layer 460 at the selected regions. Due to the low etch rate of the underlying etch-stop layer 452, over-etching may not etch into dielectric layer 450.

Optionally, in FIG. 4J, regions of etch-stop layer 452 exposed after etching the selected regions of dielectric layer 460 may be removed using another etching process and the same etch mask. The etching process may be different from the etching process for etching dielectric layer 460, and may have an etch selectivity that preferentially etches etch-stop layer 452 and have a low etch rate for the dielectric material of the underlying dielectric layer 450. Therefore, the etch time can be sufficiently long to fully remove etch-stop layer 452 at the exposed area, without etching into dielectric layer 450.

As shown in FIG. 4J, a staircase dielectric structure including at least three steps may be formed after the processing shown in FIGS. 4A-4J. Each of the three steps may have a uniform height. Additional etch-stop layers and patterned dielectric layers may be formed using additional cycles of deposition and etching of the etch-stop layer and dielectric layer as described above to form additional steps of the staircase dielectric structure.

FIG. 4K shows that, after the formation of the staircase dielectric structure, a metal layer 470 may be formed on the semiconductor wafer. Metal layer 470 may cover the staircase dielectric structure and the exposed drain electrical contact and source electrical contact. Metal layer 470 may be formed by, for example, metal sputtering, and may include, for example, a metal or a metal alloy, such as Cu, Al, W, Ti, Au, Ni, Pt, TiW, TiN, TaN, TiWAl, TiAlN, or a combination thereof.

As shown in FIG. 4L, metal layer 470 may be patterned by selectively etching some regions of metal layer 470. Metal layer 470 may be patterned to, for example, isolate the drain electrical contact and the source electrical contact, and set the desired length of the third field plate. In the illustrated example, metal layer 470 may be patterned to form three field plates on the staircase dielectric structure, such as a first field plate 472, a second field plate 474, and a third field plate 476. The three field plates have different heights, and thus the corresponding field plate transistors may have different threshold voltages (e.g., pinch-off voltages). A desired electric field profile in the channel layer of the HEMT may be achieved by selecting the appropriate heights and lengths of the field plates.

In the processing flow shown in FIGS. 4A-4L, the deposited dielectric layers at the drain and source areas may be removed while forming the staircase dielectric structure. In some other examples, the deposited dielectric layers at the drain region and/or the source region may be removed after forming the staircase dielectric structure, and the metal layer deposited on the semiconductor wafer may form the field plates on the staircase dielectric structure and also form the drain electrical contact and/or source electrical contact.

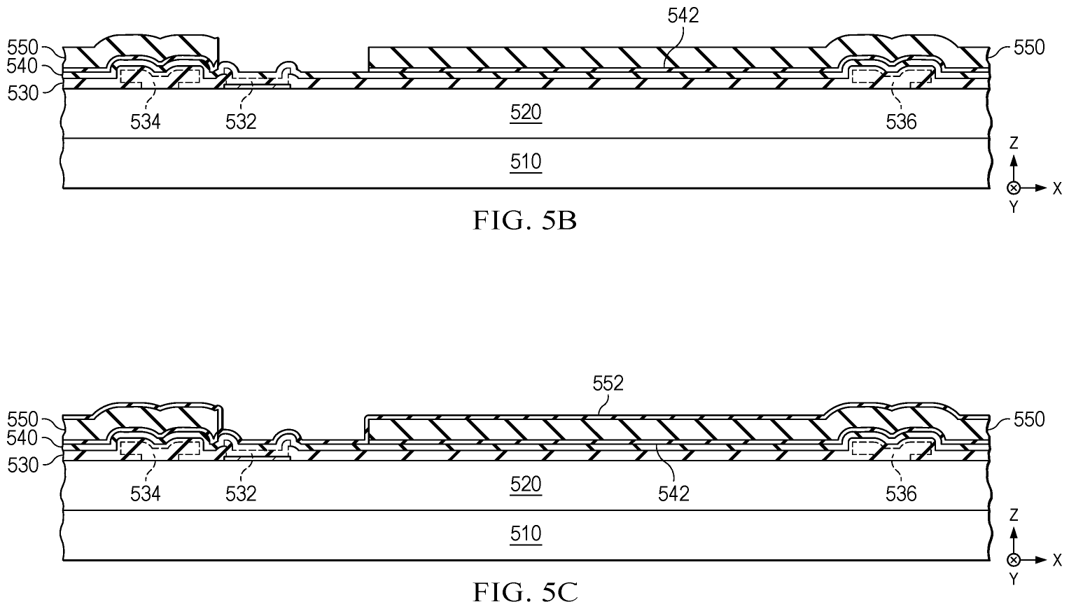

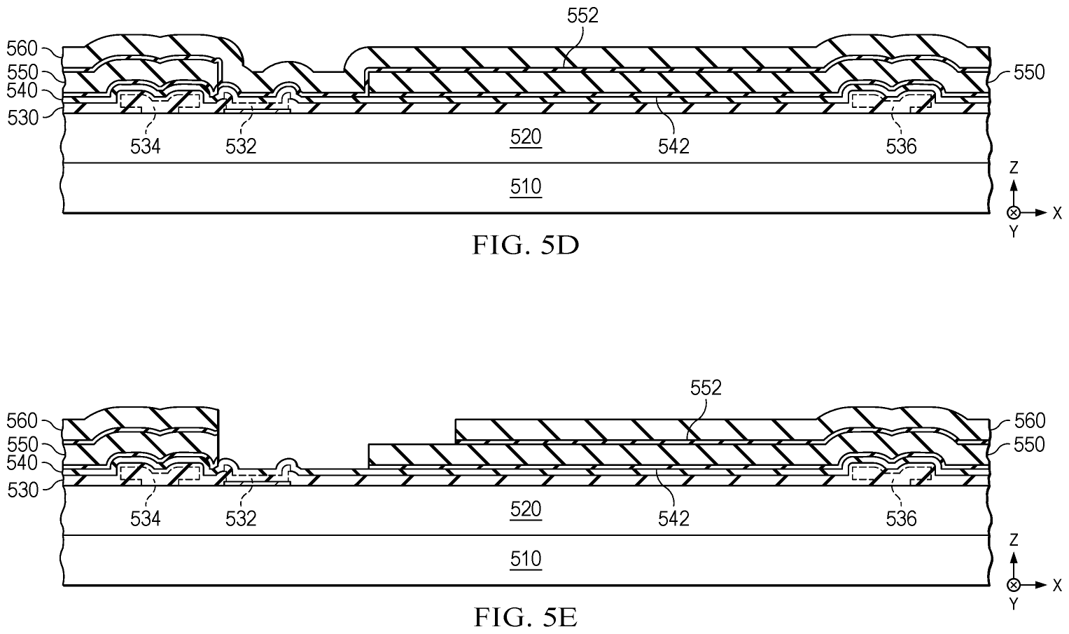

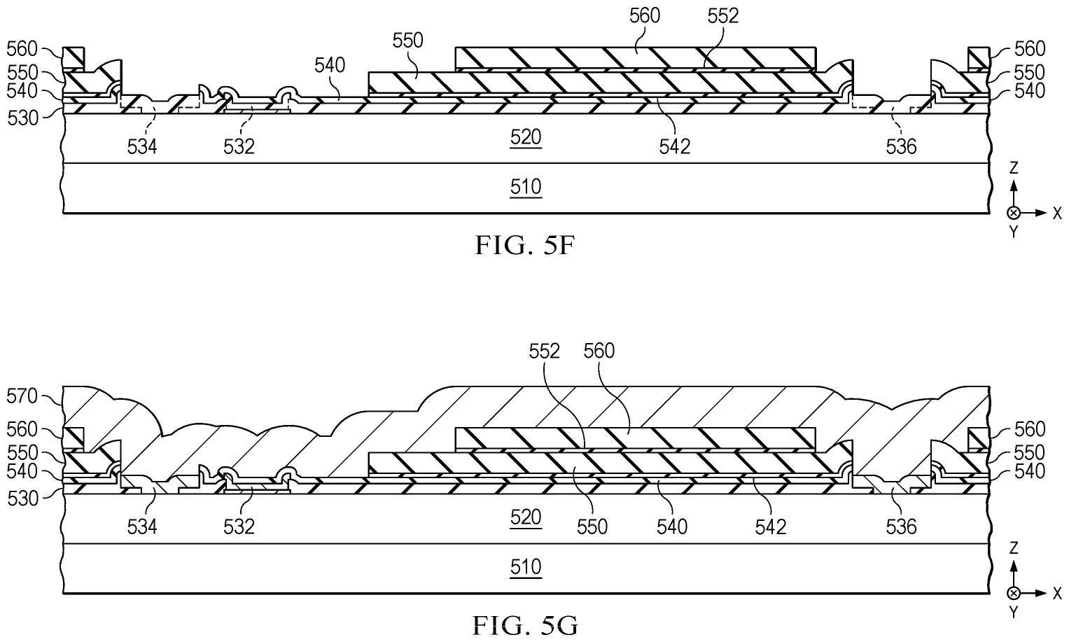

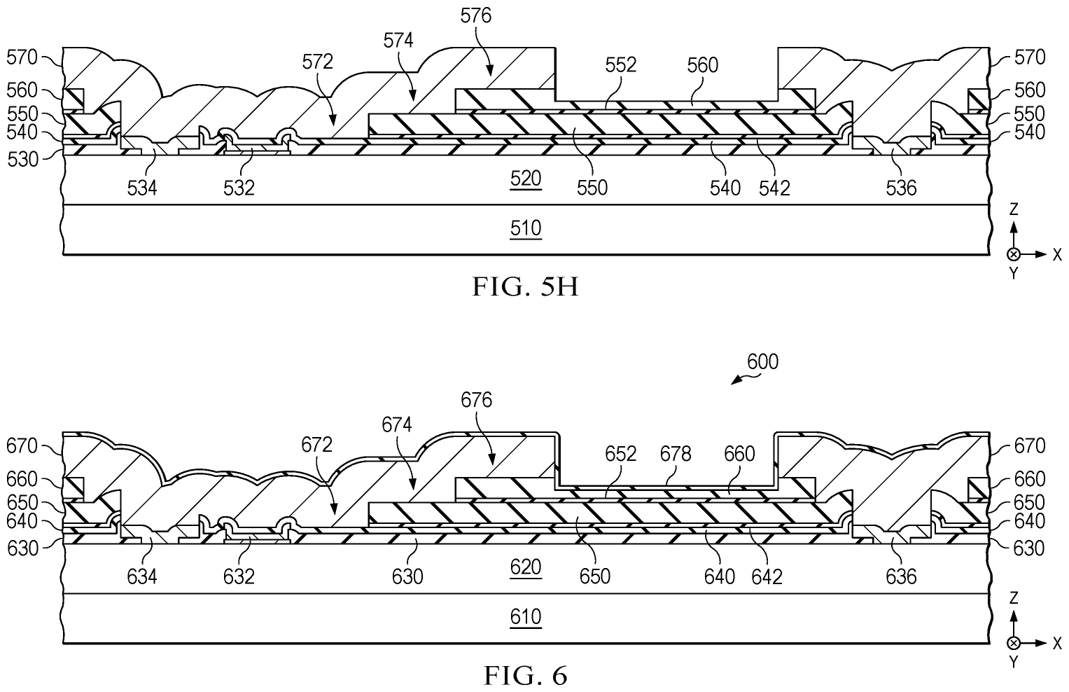

FIGS. 5A, 5B, 5C, 5D, 5E, 5F, 5G, and 5H illustrate another example of a process of fabricating an HEMT (e.g., HEMT 300) including multiple field plates using etch-stop layers. FIG. 5A shows a semiconductor wafer including a substrate 510, epitaxial layers 520 on substrate 510, and a gate structure 532, a source structure 534, and a drain structure 536 formed on epitaxial layers 520. Substrate 510 may be similar to substrate 410. Epitaxial layers 520 may be similar to epitaxial layers 420 and may include, for example, a channel layer and a barrier layer that form a heterostructure that may induce a 2DEG near the interface between the channel layer and the barrier layer due to the different energy band structures of the channel layer and the barrier layer.

Gate structure 532 may include a gate semiconductor layer or a gate dielectric layer over an upper surface of the barrier layer of epitaxial layers 520, and may also include a gate electrical contact (e.g., a gate electrode). Gate structure 532 with the gate semiconductor layer may be used to form an e-HEMT, and gate structure 532 with a gate dielectric layer may be used to form a d-HEMT. In some examples, the gate semiconductor layer may include a p-doped semiconductor layer, such as a p-doped GaN layer as described above with respect to FIG. 1A. In one example, the p-doped GaN layer at gate structure 532 may be formed by epitaxial growth on epitaxial layers 520 followed by selective area etching to remove the p-doped GaN layer in other regions. In another example, the p-doped GaN layer at gate structure 532 may be formed by depositing and patterning a dielectric layer 530 to expose epitaxial layers 520 at the gate region, followed by selective area growth of p-doped GaN on the exposed epitaxial layer 520.

Dielectric layer 530 may be deposited before or after forming the gate semiconductor layer or the gate dielectric layer. Dielectric layer 530 may include, for example, an oxide-based material or a nitride-based material, such as silicon oxide (e.g., PSG), aluminum oxide, silicon nitride, and the like. Dielectric layer 530 may be patterned to expose epitaxial layers 520 (e.g., the channel layer of epitaxial layers 520) at the drain region and the source region, and the gate semiconductor layer or gate dielectric layer. A metal layer may be deposited onto the exposed regions by, for example, metal deposition (e.g., sputtering), and etching and/or planarization. The deposited metal layer may form gate electrical contact, source electrical contact, and drain electrical contact. In some examples, gate electrical contact, source electrical contact, and drain electrical contact may be formed on epitaxial layers 520 before depositing dielectric layer 530.

Even though the example illustrated by FIG. 5A shows that source structure 534 and drain structure 536 may be formed in the source region and the drain region before the formation of the staircase dielectric structure, in some other examples, source structure 534 and drain structure 536 may not be formed in the processes shown in FIG. 5A, and the source structure and a drain structure may be formed after the formation of the staircase dielectric structure. In some other examples, source structure 534 and gate structure 532 may be formed in the processes shown by FIG. 5A, but drain structure 536 may not be formed in the processes shown by FIG. 5A and may be formed after the formation of the staircase dielectric structure.

A dielectric layer 540 may be deposited on the semiconductor wafer to cover the gate electrical contact, source electrical contact, and drain electrical contact (if formed already). The thickness of dielectric layer 540 may be determined based on the desired height of a first field plate, and may be controlled by, for example, controlling the deposition rate and deposition time. An etch-stop layer 542 may then be deposited on the semiconductor wafer. Etch-stop layer 542 may have an etch rate different from the etch rate of dielectric layer 540. Etch-stop layer 542 may include, for example, a dielectric material, a piezoelectric material, a semiconductor material, polysilicon, or a combination thereof. In one example, dielectric layer 540 may include SiNₓ, and etch-stop layer 542 may include Al₂O₃. Dielectric layer 540 and etch-stop layer 542 may be formed using any suitable techniques, such as ion-beam deposition, CVD, PVD, PECVD, ALD, sputtering, and the like. A dielectric layer 550 with a desired thickness may be formed on etch-stop layer 542. Dielectric layer 550 may include a dielectric material that is the same as or different from the dielectric material of dielectric layer 540, and may be formed using any suitable techniques, such as the deposition techniques described above. The thickness of dielectric layer 550 may be determined based on the desired height of a second field plate, and may be controlled by, for example, controlling the deposition rate and deposition time. Dielectric layer 550 may be conformally deposited on the semiconductor wafer, and may or may not have a flat top surface after the deposition.

FIG. 5B shows that dielectric layer 550 at selected regions, such as the gate region and a portion of the drain-access region, may be removed by, for example, dry or wet etching. The etching may have a high selectivity, and may have a high etch rate for the dielectric material in dielectric layer 550 and a very low etch rate for the material of etch-stop layer 542. An etch mask may be used to define the areas for etching. The etch time may be sufficiently long to fully remove dielectric layer 550 at the selected area. Due to the low etch rate of the underlying etch-stop layer 542, over-etching may not etch into dielectric layer 540. Optionally, regions of etch-stop layer 542 exposed after the etching of dielectric layer 550 may be removed using another etching process and the same etch mask. The etching process may be different from the etching process for etching dielectric layer 550, and may have an etch selectivity that preferentially etches etch-stop layer 542 and have a low etch rate for the dielectric material of the underlying dielectric layer 540. Therefore, the etch time can be sufficiently long to fully remove etch-stop layer 542 at the exposed area, without etching into dielectric layer 540.

FIG. 5C shows that an etch-stop layer 552 may be conformally formed on top of the semiconductor wafer. Etch-stop layer 552 may be similar to etch-stop layer 542, and may be formed using, for example, deposition techniques described above. FIG. 5D shows that a dielectric layer 560 with a desired thickness may then be formed on etch-stop layer 552. Dielectric layer 560 may include a dielectric material that is the same as or different from the dielectric material of dielectric layer 550, and may be formed using any suitable techniques, such as the deposition techniques described above. The thickness of dielectric layer 560 may be determined based on the desired height of a third field plate, and may be controlled by, for example, controlling the deposition rate and deposition time. Dielectric layer 560 may be conformally deposited on the semiconductor wafer, and may or may not have a flat top surface after the deposition.

FIG. 5E shows that dielectric layer 560 at selected regions, such as the gate region and some portions of the drain-access region, may be removed by, for example, dry or wet etching. The etching may have a high selectivity, such as a high etch rate for the dielectric material in dielectric layer 550 and a very low etch rate for the material of etch-stop layer 552. An etch mask may be used to define the selected regions for etching. The etch time may be sufficiently long to fully remove dielectric layer 560 at the selected regions. Due to the low etch rate of the underlying etch-stop layer 552, over-etching may not etch into dielectric layer 550. Optionally, regions of etch-stop layer 552 exposed after etching the selected regions of dielectric layer 560 may be removed using another etching process and the same etch mask. The etching process may be different from the etching process for etching dielectric layer 560, and may have an etch selectivity that preferentially etches etch-stop layer 552 and have a low etch rate for the dielectric material of the underlying dielectric layer 550. Therefore, the etch time can be sufficiently long to fully remove etch-stop layer 552 at the exposed area, without etching into dielectric layer 550.

As shown in FIG. 5E, a staircase dielectric structure including at least three steps may be formed after the processing shown in FIGS. 5A-5E. Each of the three steps may have a uniform height. Additional etch-stop layers and patterned dielectric layers may be formed using additional cycles of deposition and etching of the etch-stop layer and dielectric layer as described above to form additional steps of the staircase dielectric structure.

In FIG. 5F, the dielectric layers and the etch-stop layers formed at the drain region and the source regions, including, for example, dielectric layers 540, 550, and 560, and etch-stop layers 542 and 552, may be removed by etching. The etching may expose the drain electrical contact and the source electrical contact. In examples where the drain electrical contact and/or the source electrical contact are not formed in the processes shown by FIG. 5A, the etching may etch into epitaxial layers 520 to expose, for example, the channel layer of epitaxial layers 520 at the drain region and/or the source region.

FIG. 5G shows that a metal layer 570 may be formed on the semiconductor wafer. Metal layer 570 may cover the staircase dielectric structure and the exposed drain electrical contact and source electrical contact. Metal layer 570 may be formed by, for example, metal sputtering, and may include, for example, a metal or a metal alloy, such as Cu, Al, W, Ti, Au, Ni, Pt, TiW, TiN, TaN, TiWAl, TiAlN, or a combination thereof. In examples where the drain electrical contact and/or the source electrical contact are not formed in the processes shown by FIG. 5A, metal layer 570 may also contact the channel layer of epitaxial layers 520 to form the drain electrical contact and/or the source electrical contact.

As shown in FIG. 5H, metal layer 570 may be patterned by selectively etching some regions of metal layer 570. Metal layer 570 may be patterned to, for example, isolate the drain electrical contact and the source electrical contact, and set the desired length of the third field plate. In the illustrated example, metal layer 570 may be patterned to form three field plates on the staircase dielectric structure, such as a first field plate 572, a second field plate 574, and a third field plate 576. The three field plates have different heights, and thus the corresponding field plate transistors may have different threshold voltages (e.g., pinch-off voltages). A desired electric field profile in the channel layer of the HEMT may be achieved by selecting the appropriate heights and lengths of the field plates.

As described above, in some examples, charges may be introduced onto the etch-stop layers to further modify the electric field in the channel layer and achieve the desired electric field profile, and also tune the electron density in the channel layer, threshold voltages of field plate transistors, static on-state resistance and dynamic on-state resistance of the channel, gate-to-drain capacitance, and the like. In some examples, in addition to or as an alternative to gate semiconductor layer, an etch-stop layer may be used to store charges at the gate structure to control the gate threshold voltage of the core transistor of the HEMT.

FIG. 6 illustrates an example of an HEMT 600 including multiple field plates and charged etch-stop structures. HEMT 600 may be formed by, for example, the processes described above with respect to FIGS. 4A-5H. In the illustrated example, HEMT 600 includes a substrate 610, epitaxial layers 620 grown on substrate 610, and a gate structure 632, a source structure 634, and a drain structure 636 formed on epitaxial layers 620. Substrate 610 may be similar to substrate 105, 210, 310, 410, or 510. Epitaxial layers 620 may be similar to epitaxial layers 220, 320, 420, or 520, and may include, for example, a channel layer and a barrier layer that form a heterostructure that may induce a 2DEG near the interface between the channel layer and the barrier layer due to the different energy band structures of the channel layer and the barrier layer. Multiple dielectric layers 630, 640, 650, and 660 may be deposited and patterned (e.g., etched using etch-stop layers) to form a staircase dielectric structure in the drain-access region between the drain and gate as described above. The dielectric layers may include, for example, SiO₂, SiNₓ, and/or Al₂O₃ layers. The staircase dielectric structure may include a plurality of planar steps with well-controlled heights. A metal layer 670 may be formed (e.g., by sputtering) on the staircase dielectric structure and patterned to form multiple field plates with different heights, such as field plates 672, 674, and 676. The metal layer may include, for example, Cu, Al, W, Ti, Au, Ni, Pt, TiW, TiN, TaN, TiWAl, TiAlN, or a combination thereof. In the example shown in FIG. 6, the field plates may be connected to the source electrical contact. In other examples, the field plates may be connected to the gate electrical contact, the source electrical contact, other voltage sources, or a combination thereof.

Etch-stop layers such as etch-stop layers 642 and 652 may be used to control the etching of the dielectric layers so that the etching may not etch into the underlying dielectric layer. In some examples, one or more of etch-stop layers 642 and 652 may be charged. In some examples, an etch-stop layer 678 may be deposited and patterned after forming metal layer 670 to form a charge storing layer on dielectric layer 660. In some examples, etch-stop layer 678 may be deposited on dielectric layer 660 and patterned to form a charge storing layer, before forming metal layer 670, where the patterned etch-stop layer 678 may be used as the etch stop for patterning metal layer 670, such that the etching of metal layer 670 in the drain-access region may not etch into dielectric layer 660 to reduce the thickness and thickness uniformity of dielectric layer 660. The charge density (or the amount of charging) on each etch-stop layer may be selected to control the electric field and electron density of the channel layer, the threshold voltages of the field plate transistors, static on-state resistance and dynamic on-state resistance of the channel layer, the gate-to-drain capacitance, and the like.

The etch-stop layers may include, for example, a dielectric material, a piezoelectric material, a semiconductor material, polysilicon, or a combination thereof. Other materials that have etch rates different from the etch rates of the dielectric layers may also be used in the etch-stop layers. Various techniques may be used to add charges to the etch-stop layers, and the technique used may depend on the material of the etch-stop layer. In one example, an etch-stop layer (e.g., an aluminum oxide layer) may be formed by ALD, where charges (e.g., negative charges) may be introduced in-situ onto the etch-stop layer (e.g., at the interface between the etch-stop layer and the dielectric layer) during the ALD deposition of the etch-stop layer. For example, an Al₂O₃ etch-stop layer may be conformally formed on a semiconductor wafer by cyclic exposure of the semiconductor wafer to hydrogen (H2) plasma and trimethylaluminum (TMA). The negative charges may at least partially deplete the underlying 2DEG and thus may change the threshold voltage of the corresponding field plate transistor as described above.

In some examples, negative or positive charges may be introduced onto an etch-stop layer by implanting charged particles into the etch-stop layer, such as fixed charge shallow implanting for controlling the threshold voltages of field effect transistors (FETs). In some examples, the etch-stop layer may include a piezoelectric material such as piezoelectric aluminum nitride (AlN), and charges may be introduced onto the surface of the etch-stop layer when the piezoelectric material is exposed to stress or electric field. In some examples, the etch-stop layer may include polysilicon, and charges may be introduced onto the interface between the dielectric material layer and the polysilicon, where the polysilicon may be formed by, for example, depositing a dielectric material and doping the dielectric material with silicon. Other materials that have etch rates different from the etch rates of the dielectric layers may also be used in the etch-stop layers. Other techniques may also be used to introduce charges onto the etch-stop layers. The charge densities on different etch-stop layers may be different, and may be individually adjusted to control the electron density of the underlying 2DEG and the threshold voltages of the field plate transistors. For example, the charge density may be the highest on etch-stop layer 678, and may be lower on etch-stop layer 642 or in the gate structure (if charges are introduced in the gate structure as described above).

In some examples, the staircase dielectric structure may include many steps with small step heights and/or small step widths to approximate a slanted dielectric structure with one or more slopes on a sidewall. Therefore, the metal layer formed on the staircase dielectric structure may have approximately continuously varying heights, and the corresponding field plate transistors may have approximately continuously varying threshold voltages. As a results, the number of peaks in the electric field profile caused by the discontinuities between adjacent field plates as shown in FIG. 1B may be reduced, the electric field near the gate of the HEMT may be reduced to improve the gate TDDB, and the breakdown voltage may be improved. In some examples, edges of the dielectric layers in the staircase dielectric structure may be slanted so that the staircase dielectric structure may have regions with continuously varying thicknesses between adjacent steps, and thus the corresponding field plate transistors in some drain-access regions may have continuously varying threshold voltages, to reduce the number of peaks in the electric field profile caused by discontinuities between adjacent field plates, and also reduce the electric field near the gate of the HEMT. In some examples, as to be described below, the thickness between adjacent steps can be reduced, and a relatively large number of steps can be formed in the dielectric structure to form a relatively large number of field plates to approximate a slanted field plate.

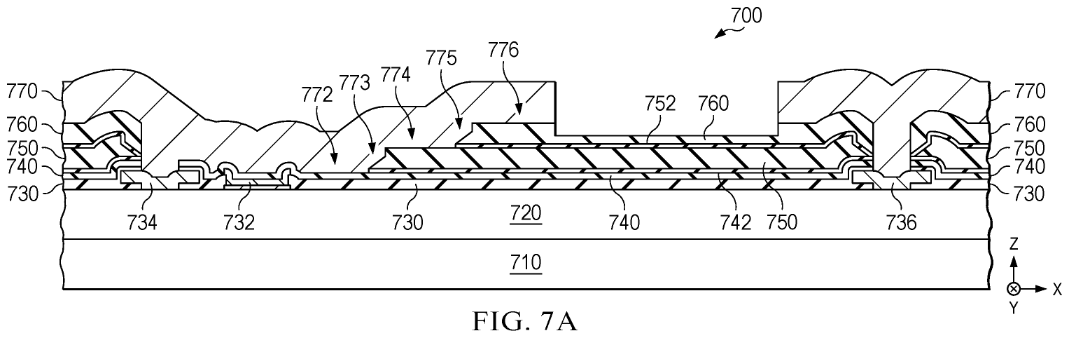

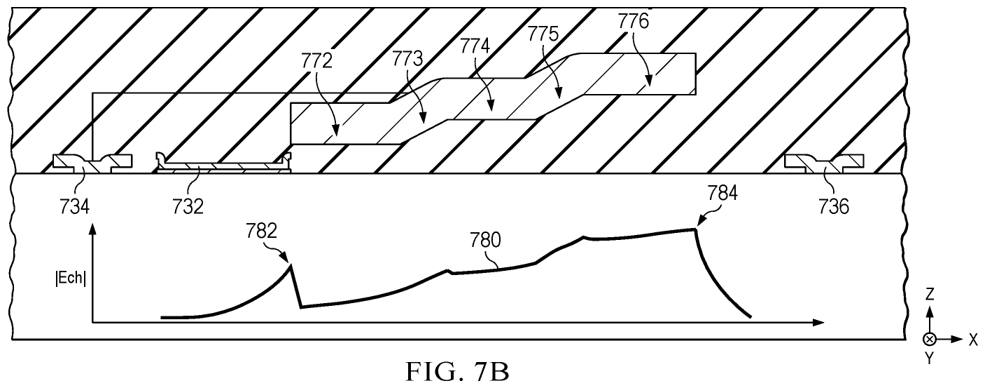

FIG. 7A illustrates an example of an HEMT 700 including slanted field plates. HEMT 700 may be similar to HEMT 300 or HEMT 600. HEMT 700 may be formed by, for example, the processes described above with respect to FIGS. 4A-5H. In the illustrated example, HEMT 700 includes a substrate 710, epitaxial layers 720 grown on substrate 710, and a gate structure 732, a source structure 734, and a drain structure 736 formed on GaN-based layers 720. Substrate 710 may be similar to substrate 105, 210, 310, 410, 510, or 610. Epitaxial layers 720 may be similar to epitaxial layers 220, 320, 420, 520, or 620, and may include, for example, a channel layer and a barrier layer that form a heterostructure that may induce a 2DEG near the interface between the channel layer and the barrier layer due to the different energy band structures of the channel layer and the barrier layer. Multiple dielectric layers 730, 740, 750, and 760 may be deposited and patterned (e.g., etched using etch-stop layers) to form a staircase dielectric structure in the drain-access region between the drain and gate as described above. The dielectric layers may include, for example, SiO₂, SiNₓ, and/or Al₂O₃ layers. The staircase dielectric structure may include a plurality of planar steps with well-controlled heights.

In HEMT 700, sidewalls of dielectric layers 750 and 760 may be slanted. The slanted sidewalls of dielectric layers 750 and 760 may be formed by, for example, wet etching that may etch both vertically and horizontally, slanted dry etching where the etching beam may be slanted with respect to a surface-normal direction of dielectric layers 750 and 760, or gray-scale lithography.

Etch-stop layers such as etch-stop layers 742 and 752 may be used to control the etching of the dielectric layers as described above, so that the etching may not etch into the underlying dielectric layer. In some examples, one or more of etch-stop layers 742 and 752 may be charged. The amount of charging or the charge density on each etch-stop layer may be selected to control the electric field and electron density of the channel layer, the threshold voltages of the field plate transistors, static on-state resistance and dynamic on-state resistance of the channel layer, the gate-to-drain capacitance, and the like.

A metal layer 770 may be formed (e.g., by sputtering) on the staircase dielectric structure, and may be patterned to form a continuous field plate structure that includes multiple field plates with different heights over epitaxial layer 620, such as field plates 772, 774, and 776. The metal layer may include, for example, Cu, Al, W, Ti, Au, Ni, Pt, TiW, TiN, TaN, TiWAl, TiAlN, or a combination thereof. Due to the slanted edges of dielectric layers 750 and 760, metal layer 770 may form a slanted field plate 773 with a varying height between field plates 772 and 774, and a slanted field plate 775 with a varying height between field plates 774 and 776. Therefore, the discontinuities in the heights of the continuous field plate structure can be reduced, and the discontinuities in the threshold voltages of the corresponding field plate transistors can also be reduced. In the example shown in FIG. 7A, the field plates may be connected to the source electrical contact. In other examples, the field plates may be connected to the gate electrical contact, the source electrical contact, other voltage sources, or a combination thereof.

FIG. 7B illustrates an example of modulating the electric field in the channel layer of HEMT 700 of FIG. 7A using field plates. FIG. 7B shows a continuous field plate structure that includes field plates 772, 773, 774, 775, and 776. Field plates 772, 773, 774, 775, and 776 may have different heights from the channel layer, and etch-stop layers 742 and 752 may have stored charges. As illustrated, there may not be discontinuities in the heights of the continuous field plate structure. Therefore, there may not be discontinuities in the threshold voltages of the corresponding field plate transistors. The threshold voltages of the corresponding field plate transistors and the electron density in the channel layer of HEMT 700 may both vary in the x direction.

A graph 780 in FIG. 7B shows an example of the electric field profile in the channel layer of HEMT 700 when HEMT is in the off state and the drain voltage is high. As illustrated, because of the discontinuity between gate structure 732 and the continuous field plate structure that is connected to source structure 734, the electric field in the channel layer of HEMT 700 may have a first peak 782 near the edge of gate structure 732, and may then drop as described above with respect to FIG. 1B. In the channel regions under the continuous field plate structure, the electric field may increase at different slopes, may reach a peak 784 near the edge of the continuous field plate structure, and may then drop in a direction towards drain structure 736 (e.g., the x direction). The total area under curve 780 may represent the voltage difference between the drain and source (VDS) of HEMT 700, which can be high before the electric field in the channel layer is sufficiently high to cause breakdown of HEMT 700. In addition, under a given drain bias condition, the peak electric field in the channel layer of HEMT 700 can be lower than the peak electric field in the channel layer of an HEMT without the continuous field plate structure, due to the larger region of the channel layer that sustains high electric field and large voltage drop. Therefore, current collapse and the dynamic on-state resistance of HEMT 700 can be low.

With the more precise control of the thicknesses of the dielectric layers using the fabrication processes disclosed herein, other passive or active devices may be fabricated during the process flow for fabricating the HEMT, and thus may be integrated with the HEMT. For example, capacitors may be formed by various structures in the HEMTs disclosed herein. In some examples, planer inductors may be fabricated using the fabrication processes disclosed herein and may be monolithically integrated with the HEMT.

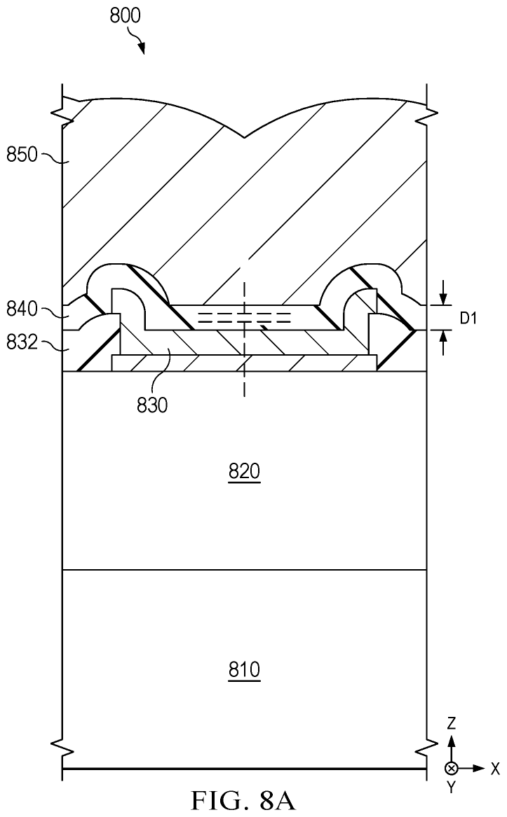

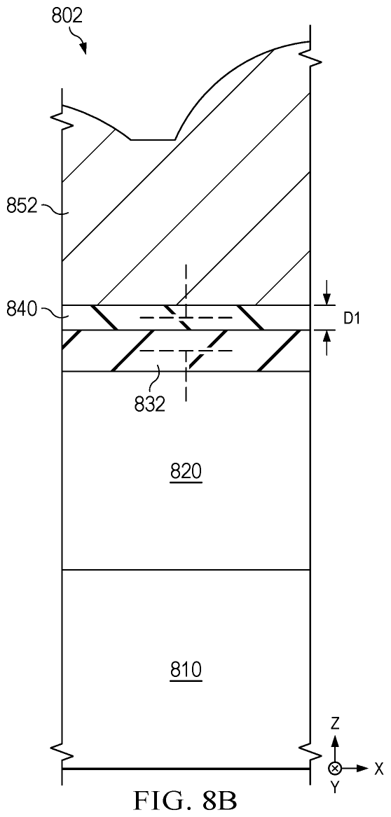

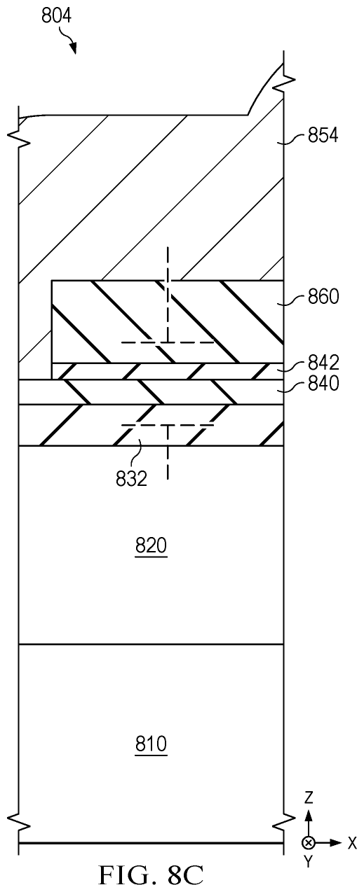

FIGS. 8A, 8B, and 8C illustrate examples of capacitors integrated with an HEMT in a semiconductor device. As described above, the HEMT may include epitaxial layers 820 grown on a substrate 810. The HEMT may also include a gate structure 830, a drain structure, and a source structure formed on epitaxial layers 820. The HEMT may further include field plates over a staircase dielectric structure fabricated using techniques disclosed herein. Various structures in the HEMT may form capacitors of different capacitance values.

FIG. 8A shows a first capacitor formed in a gate region 800 of the HEMT. The first capacitor may be formed by gate structure 830 (e.g., a gate electrical contact such as a metal gate electrode), a dielectric layer 840, and a metal layer 850. Metal layer 850 may be part of a metal layer that forms a continuous field plate structure, such as metal layer 370, 470, 570, 670, or 770 described above. Dielectric layer 840 may have a low thickness, such that the first capacitor may have a high capacitance in each unit area.

FIG. 8B shows a second capacitor formed in a first field plate region 802 of the HEMT. The second capacitor may be formed by a channel layer of epitaxial layers 820, a dielectric layer 832 and a dielectric layer 840, and a first field plate 852 that may be part of the continuous field plate structure. The thicknesses of dielectric layer 832 and dielectric layer 840 may be controlled by controlling the dielectric deposition processes. The second capacitor may have a lower capacitance in each unit area than the first capacitor because the dielectric layer in second capacitor includes both dielectric layer 832 and dielectric layer 840.

FIG. 8C shows a third capacitor formed in a second field plate region 804 of the HEMT. The third capacitor may be formed by the channel layer of epitaxial layers 820, dielectric layer 832, dielectric layer 840, an etch-stop layer 842, a dielectric layer 860, and a second field plate 854 that may be part of the continuous field plate structure. The thicknesses of dielectric layer 832, dielectric layer 840, and dielectric layer 860 may be controlled by controlling the dielectric deposition processes. Because etch-stop layers are used to form the staircase dielectric structure, the total thickness of the dielectric layers between epitaxial layers 820 and second field plate 854 can be more precisely controlled, and thus the capacitance of the third capacitor may be more precisely controlled, even if there are process variations. The third capacitor may have a lower capacitance in each unit area than the second capacitor because of the thicker dielectric material in the third capacitor. In addition, the charges built in etch-stop layer 842 may also change the capacitance of the third capacitor.

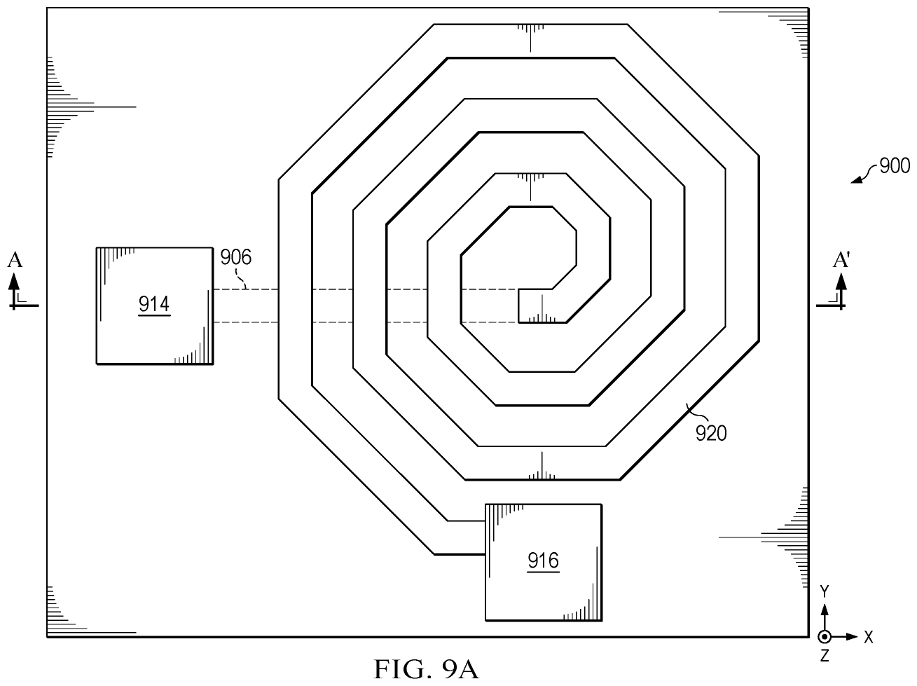

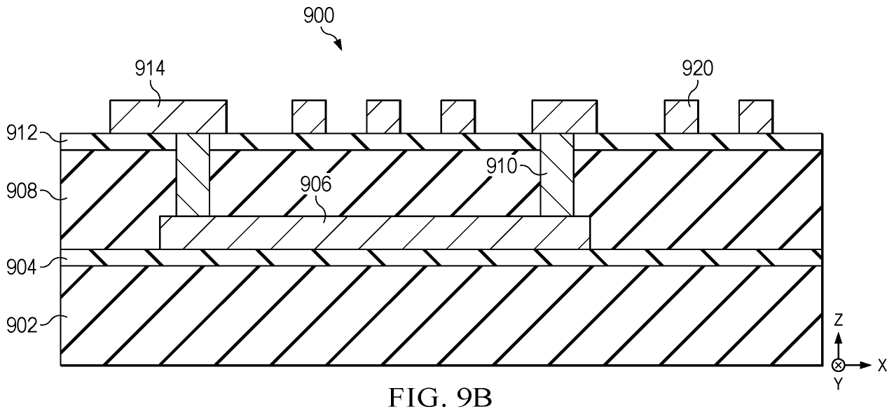

FIGS. 9A and 9B illustrates an example of an inductor 900 formed using techniques disclosed herein. FIG. 9A is a top view of inductor 900, and FIG. 9B is a cross-sectional view of inductor 900 along a line A-A′. In the illustrated example, inductor 900 may include a planar inductor 920 formed on a metal layer, and planar inductor 920 may be connected to pads 914 and 916 using vias 910 and a metal interconnect 906 formed in another metal layer. Two dielectric layers 902 and 908 and two etch-stop layers 904 and 912 may be used to form inductor 900. The dielectric layers and etch-stop layers may include materials described above.

In the illustrated example, etch-stop layer 904 may be formed on dielectric layer 902. A metal layer may be formed on etch-stop layer 904, and may be etched using etch-stop layer 904 to form metal interconnect 906. Dielectric layer 908 may be deposited over etch-stop layer 904 and metal interconnect 906. Etch-stop layer 912 may be formed on dielectric layer 908. Etch-stop layer 912 and dielectric layer 908 may be etched to form holes or trenches, which may be filled with one or more metal materials (e.g., including an adhesion layer, a diffusion barrier, and a metal) to form vias 910 (or metal plugs). A metal layer may then be formed (e.g., by sputtering) on etch-stop layer 912. The metal layer may be patterned by etching using an etch mask and etch-stop layer 912 to form planar inductor 920 (e.g., having a spiral structure) and pads 914 and 916 in the metal layer.

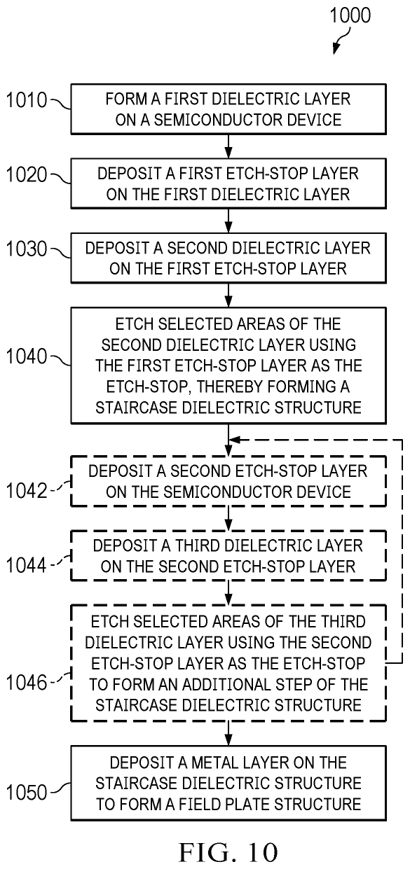

FIG. 10 includes a flowchart 1000 illustrating an example of a process of fabricating an HEMT including multiple field plates using one or more etch-stop layers. It is noted that the operations illustrated in FIG. 10 provide particular processes for fabricating examples of HEMTs disclosed herein according to certain examples. Other sequences of operations can also be performed to fabricate HEMTs according to alternative examples. For example, alternative examples may perform the operations in a different order. Moreover, the individual operations illustrated in FIG. 10 can include multiple sub-operations that can be performed in various sequences as appropriate for the individual operation. Furthermore, some operations can be added or removed depending on the particular example. In some examples, two or more operations may be performed in parallel. In some examples, two or more operations in flowchart 1000 may be performed iteratively. One of ordinary skill in the art would recognize many variations, modifications, and alternatives.

Operations at block 1010 of flowchart 1000 may include forming a first dielectric layer on a semiconductor device. The semiconductor device may include an HEMT. The HEMT may include a substrate, epitaxial layers grown on the substrate, and at least a gate structure formed on the epitaxial layers. The substrate may include, for example, substrate 105, 210, 310, 410, 510, 610, or 710. The epitaxial layers may include, for example, epitaxial layers 220, 320, 420, 520, 620, or 720, and may include, for example, a channel layer and a barrier layer that form a heterostructure that may induce a 2DEG near the interface between the channel layer and the barrier layer due to the different energy band structures of the channel layer and the barrier layer. The gate structure may include, for example, a gate semiconductor layer or a gate dielectric layer over an upper surface of the barrier layer of the epitaxial layers, and may also include a gate electrical contact (e.g., a gate electrode). In some examples, the semiconductor device may also include a source structure and/or a drain structure formed on the epitaxial layers. The source structure and the drain structure may include metal contacts that contact the channel layer at the source region and the drain region, respectively. In some examples, the first dielectric layer may include a dielectric material between the drain structure and the gate structure and between the gate structure and the source structure (e.g., dielectric layer 330, 430, 530, 630, or 730), and a dielectric layer formed over the drain structure, the gate structure, and the source structure (e.g., dielectric layer 340, 440, 540, 640, or 740). As described above, the first dielectric layer may include, for example, an oxide-based material or a nitride-based material, such as silicon oxide (e.g., PSG), Al₂O₃, SiNₓ, and the like. The first dielectric layer may be formed using any suitable techniques, such as ion-beam deposition, CVD, PVD, PECVD, ALD, sputtering, and the like. The thickness of the first dielectric layer may be determined based on the desired threshold voltage (e.g., pinch-off voltage) of a first field plate transistor.

At block 1020, a first etch-stop layer (e.g., etch-stop layer 342, 442, 542, 642, or 742) may be deposited on the first dielectric layer. The first etch-stop layer may have an etch rate different from the etch rate of the first dielectric layer under a same etching condition. The first etch-stop layer may include, for example, a dielectric material, a piezoelectric material, a semiconductor material, polysilicon, or a combination thereof. In one example, the first dielectric layer may include SiN, and first etch-stop layer may include Al₂O₃. The first etch-stop layer may be formed on the first dielectric layer using, for example, ion-beam deposition, CVD, PVD, PECVD, ALD, sputtering, and the like. In some examples, charges may be introduced onto the first etch-stop layer as described above with respect to, for example, FIG. 6, to tune the electric field and the electron density in the channel layer. For example, charges may be introduced onto the first etch-stop layer by depositing the first etch-stop layer using atomic layer deposition, by implanting charged particles into the first etch-stop layer, by depositing a piezoelectric material, by depositing a dielectric material and doping the dielectric material with silicon, and the like. The charge density on the first etch stop layer may be determined based on the desired threshold voltage (e.g., pinch-off voltage) of a second field plate transistor.

At block 1030, a second dielectric layer (e.g., dielectric layer 350, 450, 550, 650, or 750) may be deposited on the first etch-stop layer. As the first dielectric layer, the second dielectric layer may also include, for example, an oxide-based material or a nitride-based material, such as silicon oxide (e.g., PSG), Al₂O₃, SiNₓ, and the like, and may be formed using any suitable techniques, such as ion-beam deposition, CVD, PVD, PECVD, ALD, sputtering, and the like. The thickness of the second dielectric layer may be determined based on the desired threshold voltage (e.g., pinch-off voltage) of the second field plate transistor.

Operations at block 1040 may include etching selected areas of the second dielectric layer using the first etch-stop layer as the etch stop to form a staircase dielectric structure. In some examples, etching selected areas of the second dielectric layer may include etching the second dielectric layer at a gate region, a source region, and a drain region of the semiconductor device. In some examples, etching selected areas of the second dielectric layer may include etching the second dielectric layer at only the gate region of the semiconductor device. In some examples, etching selected areas of the second dielectric layer may include etching the second dielectric layer at the gate region and the source region, but not the drain region, of the semiconductor device. The etching can be performed for a sufficiently long period of time to completely remove the second dielectric layer at the selected areas. Due to the low etch rate of the first etch-stop layer between the first dielectric layer and the second dielectric layer, over-etching the second dielectric layer may not etch into the first dielectric layer. In some examples, an edge region of the remaining second dielectric layer on the side of the gate region may be etched using, for example, wet etching, slanted dry etching, or gray-scale lithography, to form a slanted sidewall. In some examples, after etching the second dielectric layer, the exposed first etch-stop layer may be removed using a different etching process that may have a higher etch rate for the first etch-stop layer but a much lower etch rate for the first dielectric layer.

Optionally, a second etch-stop layer may be deposited on the semiconductor device at block 1042, a third dielectric layer may be deposited on the second etch-stop layer at block 1044, and selected areas of the third dielectric layer may be etched using the second etch-stop layer as the etch stop at block 1046, to form an additional step of the staircase dielectric structure. The operations at blocks 1042, 1044, and 1046 may be similar to the operations at blocks 1020, 1030, and 1040 described above. In some examples, charges may be introduced onto the second etch-stop layer as described above with respect to, for example, FIG. 6, to tune the electric field and the electron density in the channel layer. The charge density on the second etch-stop layer may be determined based on the desired threshold voltage (e.g., pinch-off voltage) of a third field plate transistor. The thickness of the third dielectric layer may also be determined based on the desired threshold voltage of the third field plate transistor. In some examples, an edge region of the etched third dielectric layer may be etched to form a slanted sidewall as described above. In some examples, operations at block 1042, 1044, and 1046 may be performed iteratively to form additional steps of the staircase dielectric structure. For example, many dielectric layers with low layer heights may be formed to approximate a dielectric structure with a slanted sidewall having one or more slopes.

In some examples, the dielectric layers at the drain region and/or the source region may not be etched at blocks 1040 and 1046. After the formation of the staircase dielectric structure, the dielectric layers and etch-stop layer(s) at the drain region and/or the source region may be etched to expose the drain structure and/or the source structure, or the channel layer at the drain region and/or the source region if the drain structure and/or the source structure are not formed yet.

At block 1050, a metal layer may be deposited on the staircase dielectric structure to form a field plate structure. When the staircase dielectric structure includes many dielectric layers with low layer thicknesses to approximate a dielectric structure having a slanted sidewall, the metal layer formed on the staircase dielectric structure may have approximately continuously varying heights, and the corresponding field plate transistors may have approximately continuously varying threshold voltages. When the staircase dielectric structure includes multiple planar steps with slanted sidewalls as shown in FIGS. 7A and 7B, the field plate structure may include two or more planar field plates and one or more slanted field plates. In some examples, depositing the metal layer may also form a drain contact structure at the drain region, and/or a source contact structure at the source region.

As used herein, the term “semiconductor substrate” may refer to a semiconductor wafer without other layers or circuits formed therein, or a semiconductor wafer that includes various layers and circuits formed therein. As used herein, the term “layer” may refer to a continuous layer, or a region or portion of a layer.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT, e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately,” or “substantially” preceding a parameter means being within +/−10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description on order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

What is claimed is:

1. A semiconductor device comprising:
a semiconductor substrate;
a source electrode, a gate electrode, and a drain electrode on the semiconductor substrate;
a staircase dielectric structure on the semiconductor substrate and laterally between the gate electrode and the drain electrode, the staircase dielectric structure including:
a first dielectric layer on the semiconductor substrate;
a first etch-stop layer on the first dielectric layer; and
a second dielectric layer on the first etch-stop layer, the first dielectric layer having a first lateral dimension greater than a second lateral dimension of the second dielectric layer; and
a metal layer on the staircase dielectric structure, the metal layer including a first field plate on at least a first region of the first dielectric layer and a second field plate on at least a second region of the second dielectric layer.

2. The semiconductor device of claim 1, wherein:
the first region of the first dielectric layer has a first thickness;
the second region of the second dielectric layer has a second thickness; and
a third region of the first dielectric layer directly over the second region of the second dielectric layer has the first uniform thickness.

3. The semiconductor device of claim 1, wherein:
the first dielectric layer in the staircase dielectric structure has a first planar surface; and
the second dielectric layer in the staircase dielectric structure has a second planar surface.

4. The semiconductor device of claim 1, wherein a sidewall of the second dielectric layer in the staircase dielectric structure is slanted.

5. The semiconductor device of claim 1, wherein the first etch-stop layer includes charges stored in or on the first etch-stop layer.

6. The semiconductor device of claim 1, wherein the staircase dielectric structure further comprises:
a second etch-stop layer on the second dielectric layer; and
a third dielectric layer on second etch-stop layer,
wherein the metal layer includes a third field plate on at least a portion of the third dielectric layer.

7. The semiconductor device of claim 6, wherein a sidewall of the third dielectric layer in the staircase dielectric structure is slanted.

8. The semiconductor device of claim 6, wherein the second etch-stop layer includes charges stored in or on the second etch-stop layer.

9. The semiconductor device of claim 6, wherein the staircase dielectric structure further comprises a third etch-stop layer on at least a region of the third dielectric layer, the third etch-stop layer including charges stored in or on the third etch-stop layer.

10. The semiconductor device of claim 1, wherein the metal layer includes a planar inductor over a planar dielectric layer.

11. The semiconductor device of claim 1, further comprising a capacitor including a planar dielectric layer.

12. The semiconductor device of claim 1, wherein the first etch-stop layer covers the first region of the first dielectric layer.

13. The semiconductor device of claim 1, wherein the first etch-stop layer includes a dielectric material, a piezoelectric material, a semiconductor material, polysilicon, or a combination thereof.

14. The semiconductor device of claim 1, wherein the metal layer is electrically coupled to the source electrode or the gate electrode.

15. The semiconductor device of claim 1, wherein the semiconductor substrate includes a heterostructure formed by a channel layer and a barrier layer.

16. The semiconductor device of claim 1, further comprising a p-doped semiconductor layer or a gate dielectric layer between the gate electrode and the semiconductor substrate.

17. The semiconductor device of claim 1, wherein the staircase dielectric structure includes three or more dielectric layers that include the first dielectric layer and the second dielectric layer.

18. The semiconductor device of claim 1, wherein:
the staircase dielectric structure includes a plurality of dielectric layers; and
lateral dimensions and heights of dielectric layers of the plurality of dielectric layers are selected such that the plurality of dielectric layers approximates a slope structure.

19. A method comprising:
depositing a first dielectric layer on a semiconductor device, the semiconductor device including a channel layer and a barrier layer;
depositing a first etch-stop layer on the first dielectric layer;
depositing a second dielectric layer on the first etch-stop layer;
etching selected areas of the second dielectric layer using the first etch-stop layer as the etch stop, the etched second dielectric layer and the first dielectric layer forming a staircase dielectric structure; and
depositing a metal layer on the staircase dielectric structure to form a plurality of field plates on the staircase dielectric structure.

20. The method of claim 19, wherein depositing the first etch-stop layer on the first dielectric layer includes introducing charges in or on the first etch-stop layer.

21. The method of claim 20, wherein introducing charges in or on the first etch-stop layer includes:
depositing the first etch-stop layer using atomic layer deposition;
implanting charged particles into the first etch-stop layer;
depositing a piezoelectric material;
depositing a dielectric material and doping the dielectric material with silicon; or
a combination thereof.

22. The method of claim 19, further comprising, before depositing the metal layer:
depositing a second etch-stop layer on the semiconductor device;
depositing a third dielectric layer on the second etch-stop layer; and
etching selected areas of the third dielectric layer using the second etch-stop layer as the etch stop to form an additional step of the staircase dielectric structure.

23. The method of claim 22, wherein:
etching the selected areas of the second dielectric layer includes etching the second dielectric layer at a gate region, a source region, and a drain region of the semiconductor device; and
etching the selected areas of the third dielectric layer includes etching the third dielectric layer at the gate region, the source region, and the drain region of the semiconductor device.

24. The method of claim 22, wherein:
etching the selected areas of the second dielectric layer includes etching the second dielectric layer at a gate region of the semiconductor device;
etching the selected areas of the third dielectric layer includes etching the third dielectric layer at the gate region of the semiconductor device; and
the method further includes, before depositing the metal layer, etching the second dielectric layer and the third dielectric layer at a source region and a drain region of the semiconductor device.

25. The method of claim 22, wherein:
etching the selected areas of the second dielectric layer includes etching the second dielectric layer at a gate region and a source region of the semiconductor device;
etching the selected areas of the third dielectric layer includes etching the third dielectric layer at the gate region and the source region of the semiconductor device; and
the method further includes, before depositing the metal layer, etching the second dielectric layer and the third dielectric layer at a drain region of the semiconductor device.
